(19) United States
(12) Patent Application Publication
(10) Pub. No.: US 2024/0329518 A1
(43) Pub. Date: Oct. 3, 2024

(54) PHOTOMASK CREATING METHOD, DATA CREATING METHOD, AND ELECTRONIC DEVICE MANUFACTURING METHOD

(71) Applicant: Gigaphoton Inc., Tochigi (JP)

(72) Inventor: Koichi FUJII, Oyama-shi (JP)

(73) Assignee: Gigaphoton Inc., Tochigi (JP)

(21) Appl. No.: 18/743,805

(22) Filed: Jun. 14, 2024

Related U.S. Application Data
(63) Continuation of application No. PCT/JP2022/001247, filed on Jan. 14, 2022.

(51) Int. Cl. G03F 1/70; G03F 1/36; G03F 1/44

(52) U.S. Cl. CPC G03F 1/70; G03F 1/36; G03F 1/44

(57) ABSTRACT

Provided is an optical proximity correction method in consideration of off-axis chromatic aberration produced when a photosensitive substrate is exposed to pulse laser light having center wavelengths. A method for creating a photomask includes scanning a test wafer in a first direction with the pulse laser light via a test mask to pattern the test wafer, measuring a wafer pattern of the patterned test wafer to acquire a measured wafer pattern indicating the result of the measurement in each of divided regions arranged on a surface of the test wafer in a second direction that intersects with the first direction, creating a corrected mask pattern for creating the photomask based on a test mask pattern formed at the test mask, the measured wafer pattern, and a target pattern that is a target wafer pattern at a photosensitive substrate, and creating the photomask based on the corrected mask pattern.

### CROSS-REFERENCE TO RELATED APPLICATIONS

The present application is a continuation application of International Application No. PCT/JP2022/001247, filed on Jan. 14, 2022, the entire contents of which are hereby incorporated by reference.

### BACKGROUND

### 1. Technical Field

The present disclosure relates to a photomask creating method, a data creating method, and an electronic device manufacturing method.

### 2. Related Art

In recent years, a semiconductor exposure apparatus is required to improve the resolution thereof as semiconductor integrated circuits are increasingly miniaturized and highly integrated. To this end, reduction in the wavelength of light emitted from a light source for exposure is underway. For example, a KrF excimer laser apparatus, which outputs laser light having a wavelength of about 248 nm, and an ArF excimer laser apparatus, which outputs laser light having a wavelength of about 193 nm, are used as a gas laser apparatus for exposure.

The light from spontaneously oscillating KrF and ArF excimer laser apparatuses has a wide spectral linewidth ranging from 350 to 400 pm. A projection lens made of a material that transmits ultraviolet light, such as KrF and ArF laser light, therefore produces chromatic aberrations in some cases. As a result, the resolution of the projection lens may decrease. To avoid the decrease in the resolution, the spectral linewidth of the laser light output from the gas laser apparatus needs to be narrow enough to make the chromatic aberrations negligible. To this end, a line narrowing module (LNM) including a line narrowing element (such as etalon and grating) is provided in some cases in a laser resonator of the gas laser apparatus to narrow the spectral linewidth. A gas laser apparatus providing a narrowed spectral linewidth is hereinafter referred to as a narrowed-line laser apparatus.

### CITATION LIST

### Patent Literature

[PTL 1] WO2021/110343

### SUMMARY

In an aspect of the present disclosure, a method for creating a photomask used in photolithography using pulse laser light having plural center wavelengths includes scanning a test wafer in a first direction with the pulse laser light via a test mask to pattern the test wafer, measuring a wafer pattern of the patterned test wafer to acquire a measured wafer pattern indicating a result of the measurement in each of plural divided regions arranged on a surface of the test wafer in a second direction that intersects with the first direction, creating a corrected mask pattern for creating the photomask based on a test mask pattern formed at the test mask, the measured wafer pattern, and a target pattern that is a target wafer pattern at a photosensitive substrate, and creating the photomask based on the corrected mask pattern.

In another aspect of the present disclosure, a method for creating data on a corrected mask pattern for creating a photomask used in photolithography using pulse laser light having plural center wavelengths includes scanning a test wafer in a first direction with the pulse laser light via a test mask to pattern the test wafer, measuring a wafer pattern of the patterned test wafer to acquire a measured wafer pattern indicating a result of the measurement in each of plural divided regions arranged on a surface of the test wafer in a second direction that intersects with the first direction, and creating the corrected mask pattern based on a test mask pattern formed at the test mask, the measured wafer pattern, and a target pattern that is a target wafer pattern at a photosensitive substrate.

In still another aspect of the present disclosure, an electronic device manufacturing method includes scanning a test wafer in a first direction with pulse laser light having plural center wavelengths via a test mask to pattern the test wafer, measuring a wafer pattern of the patterned test wafer to acquire a measured wafer pattern indicating a result of the measurement in each of plural divided regions arranged on a surface of the test wafer in a second direction that intersects with the first direction, creating a corrected mask pattern for creating a photomask used in photolithography using the pulse laser light based on a test mask pattern formed at the test mask, the measured wafer pattern, and a target pattern that is a target wafer pattern at a photosensitive substrate, creating the photomask based on the corrected mask pattern, and exposing the photosensitive substrate to the pulse laser light via the photomask to manufacture electronic devices.

### BRIEF DESCRIPTION OF DRAWINGS

Embodiments of the present disclosure will be described below only by way of example with reference to the accompanying drawings.

FIG. 1 schematically shows the configuration of an exposure system according to Comparative Example.

FIG. 2 schematically shows the configuration of a laser apparatus.

FIG. 3 shows how the position of a scan field of a photosensitive substrate changes with respect to the position of pulse laser light.

FIG. 4 shows how the position of the scan field of the photosensitive substrate changes with respect to the position of the pulse laser light.

FIG. 5 shows how the position of the scan field of the photosensitive substrate changes with respect to the position of the pulse laser light.

FIG. 6 is a graph showing a cyclic change in wavelength.

FIG. 7 shows an accumulated spectrum of the pulse laser light having plural center wavelengths.

FIG. 8 shows an example in which a wafer pattern different from a target pattern is formed due to the optical proximity effect when the target pattern is used as it is as a mask pattern.

FIG. 9 shows an example in which a wafer pattern close to the target pattern is formed by using a corrected mask pattern having undergone optical proximity correction.

FIG. 10 is a conceptual view of model-based OPC in Comparative Example.

FIG. 11 is a flowchart of the model-based OPC.

FIG. 12 shows the structure of data on a measured wafer pattern.

FIG. 13 is a flowchart showing the processes of creating a model function group in detail.

FIG. 14 is a conceptual view of rule-based OPC in Comparative Example.

FIG. 15 is a flowchart of the rule-based OPC.

FIG. 16 shows the structure of data on a correction value.

FIG. 17 shows the concept of an off-axis chromatic aberration produced when the photosensitive substrate is exposed to pulse laser light having plural wavelengths.

FIG. 18 is a conceptual view of divided-model-based OPC in a first embodiment.

FIG. 19 shows plural divided regions contained in the scan field of a test wafer.

FIG. 20 is a flowchart of the divided-model-based OPC.

FIG. 21 shows the structures of data on measured wafer patterns.

FIG. 22 is a flowchart showing the processes of creating model function groups in detail.

FIG. 23 shows an example of the model function groups.

FIG. 24 is a conceptual view of common-model-based OPC in a second embodiment.

FIG. 25 shows the plural divided regions contained in the scan field of the test wafer.

FIG. 26 is a flowchart of the common-model-based OPC.

FIG. 27 is a flowchart showing the process of creating the model function group in detail.

FIG. 28 shows the structure of data on differences.

FIG. 29 is a conceptual view of divided-rule-based OPC in a third embodiment.

FIG. 30 is a flowchart of the divided-rule-based OPC.

FIG. 31 shows the structure of data on the correction values.

### DETAILED DESCRIPTION

### Contents

1. Comparative Example
1.1 Exposure system
1.1.1 Configuration
1.1.2 Operation
1.2 Laser apparatus 100
1.2.1 Configuration
1.2.2 Operation
1.3 Line narrowing module 14
1.3.1 Configuration
1.3.2 Operation
1.4 Scanning exposure
1.5 Cyclic wavelength change and accumulated spectrum
1.6 Optical proximity correction (OPC)
1.6.1 Overview
1.6.2 Model-based OPC
1.6.3 Rule-based OPC
1.7 Problems with Comparative Example
2. Divided-model-based OPC
2.1 Operation
2.2 Effects
3. Common-model-based OPC
3.1 Operation
3.2 Effects
4. Divided-rule-based OPC
4.1 Operation
4.2 Effects
5. Others

Embodiments of the present disclosure will be described below in detail with reference to the drawings. The embodiments described below show some examples of the present disclosure and are not intended to limit the content of the present disclosure. Furthermore, all configurations and operations described in the embodiments are not necessarily essential as configurations and operations in the present disclosure. The same elements has the same reference character, and no redundant description of the same component will be made.

### 1. Comparative Example

### 1.1 Exposure System

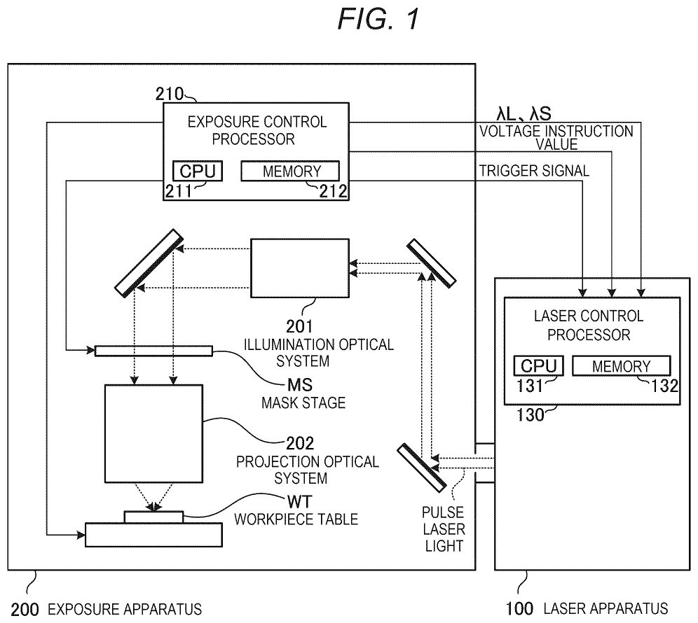

FIG. 1 schematically shows the configuration of an exposure system according to Comparative Example. Comparative Example in the present disclosure is an aspect that the applicant is aware of as known only by the applicant, and is not a publicly known example that the applicant is self-aware of.

The exposure system includes a laser apparatus 100 and an exposure apparatus 200. FIG. 1 shows the laser apparatus 100 in a simplified form.

The laser apparatus 100 includes a laser control processor 130. The laser control processor 130 is a processing apparatus including a memory 132, which stores a control program, and a CPU (central processing unit) 131, which executes the control program. The laser control processor 130 is specially configured or programmed to carry out a variety of processes described in the present disclosure. The laser apparatus 100 is configured to output pulse laser light toward the exposure apparatus 200.

### 1.1.1 Configuration

The exposure apparatus 200 includes an illumination optical system 201, a projection optical system 202, and an exposure control processor 210, as shown in FIG. 1.

The illumination optical system 201 illuminates a mask pattern of a photomask that is not shown but is placed on a mask stage MS with the pulse laser light incident from the laser apparatus 100.

The projection optical system 202 performs reduction projection on the pulse laser light having passed through the photomask to bring the pulse laser light into focus on a workpiece that is not shown but is placed on a workpiece table WT. The workpiece is a photosensitive substrate, such as a semiconductor wafer coated with a photoresist film.

The exposure control processor 210 is a processing apparatus including a memory 212, which stores a control program, and a CPU 211, which executes the control program. The exposure control processor 210 is specially configured or programmed to carry out a variety of processes described in the present disclosure. The exposure control processor 210 oversees the control on the exposure apparatus 200 and transmits and receives a variety of parameters and signals to and from the laser control processor 130.

### 1.1.2 Operation

The exposure control processor 210 transmits the variety of parameters including a target long wavelength λL, a target short wavelength λS, and a voltage instruction value, and a trigger signal to the laser control processor 130. The laser control processor 130 controls the laser apparatus 100 in accordance with the parameters and the signal.

The exposure control processor 210 translates the mask stage MS and the workpiece table WT in opposite directions to each other in synchronization. The workpiece is thus exposed to the pulse laser light having reflected the mask pattern.

The mask pattern is transferred onto a photosensitive substrate by the photolithography described above. Plural steps that follow the exposure step allow manufacture of electronic devices.

### 1.2 Laser Apparatus 100

### 1.2.1 Configuration

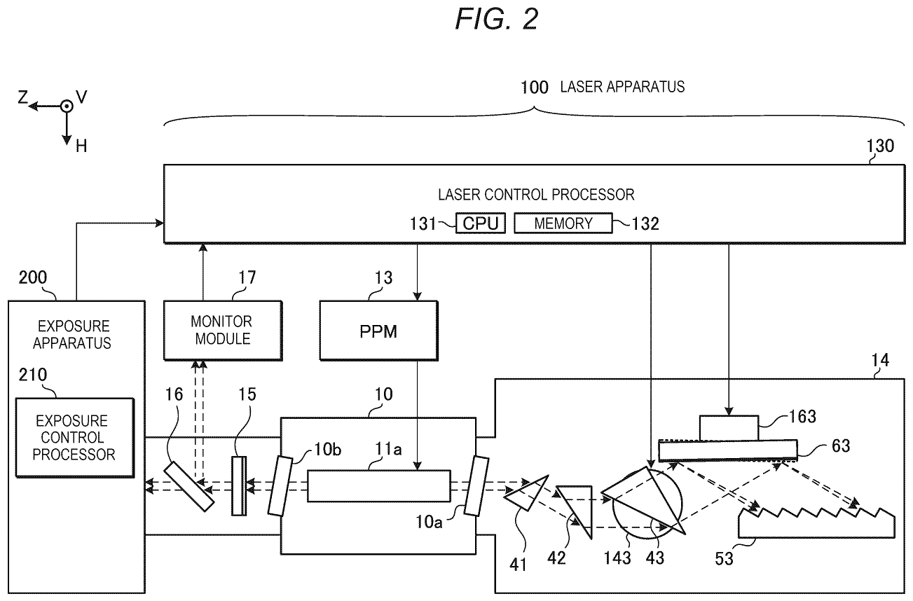

FIG. 2 schematically shows the configuration of the laser apparatus 100. A V-axis, an H-axis, and a Z axis, which are perpendicular to one another, are shown in FIG. 2. In FIG. 2, the laser apparatus 100 is viewed in the −V direction, and the exposure apparatus 200 is shown in a simplified form.

The laser apparatus 100 includes a laser chamber 10, a pulse power module (PPM) 13, a line narrowing module 14, an output coupling mirror 15, and a monitor module 17 as well as the laser control processor 130. The line narrowing module 14 and the output coupling mirror 15 constitute an optical resonator.

The laser chamber 10 is disposed in the optical path of the optical resonator. The laser chamber 10 is provided with windows 10a and 10b.

The laser chamber 10 accommodates a discharge electrode 11a and a discharge electrode that is not shown but is paired therewith. The discharge electrode that is not shown is located so as to coincide with the discharge electrode 11a in the direction of the V-axis. The laser chamber 10 is filled with a laser gas containing, for example, an argon or krypton gas as a rare gas, a fluorine gas as a halogen gas, and a neon gas as a buffer gas.

The pulse power module 13 includes a switch that is not shown and is connected to a charger that is not shown.

The line narrowing module 14 includes prisms 41 to 43, a grating 53, and a mirror 63. The line narrowing module 14 will be described later in detail.

The output coupling mirror 15 includes a partially reflective mirror.

A beam splitter 16 is disposed in the optical path of the pulse laser light output via the output coupling mirror 15, transmits part of the pulse laser light at high transmittance, and reflects the other part of the pulse laser light. The monitor module 17 is disposed in the optical path of the pulse laser light reflected off the beam splitter 16.

### 1.2.2 Operation

The laser control processor 130 acquires the variety of parameters including the target long wavelength λL, the target short wavelength λS, and the voltage instruction value from the exposure control processor 210. The laser control processor 130 transmits a control signal to the line narrowing module 14 based on the target long wavelength λL and the target short wavelength λS.

The laser control processor 130 receives the trigger signal from the exposure control processor 210. The laser control processor 130 transmits an oscillation trigger signal based on the trigger signal to the pulse power module 13. The switch provided in the pulse power module 13 is turned on when the pulse power module 13 receives the oscillation trigger signal from the laser control processor 130. When the switch is turned on, the pulse power module 13 generates a pulse-shaped high voltage from the electric energy charged in the charger, and applies the high voltage to the discharge electrode 11a.

When the high voltage is applied to the discharge electrode 11a, discharge occurs in the discharge space between the discharge electrode 11a and the discharge electrode that is not shown. The energy of the discharge excites the laser gas in the laser chamber 10, and the excited laser gas transitions to a high energy level. Thereafter, when the excited laser gas transitions to a low energy level, the laser gas emits light having a wavelength according to the difference between the energy levels.

The light generated in the laser chamber 10 exits out of the laser chamber 10 via the windows 10a and 10b. The light having exited via the window 10a enters the line narrowing module 14. Light having a desired wavelength and therearound out of the light having entered the line narrowing module 14 is deflected back by the line narrowing module 14 and returns into the laser chamber 10.

The output coupling mirror 15 transmits and outputs part of the light having exited via the window 10b and reflects the remaining light back into the laser chamber 10.

The light output from the laser chamber 10 thus travels back and forth between the line narrowing module 14 and the output coupling mirror 15. The light is amplified whenever passing through the discharge space in the laser chamber 10. Furthermore, the light is narrowed in terms of linewidth whenever deflected back by the line narrowing module 14, and becomes light having a steep wavelength distribution having a center wavelength being part of the range of wavelengths selected by the line narrowing module 14. The light thus having undergone the laser oscillation and the line narrowing operation is output as the pulse laser light via the output coupling mirror 15.

The monitor module 17 measures the center wavelength of the pulse laser light and transmits the measured wavelength to the laser control processor 130. The laser control processor 130 performs feedback control on the line narrowing module 14 based on the measured wavelength.

The pulse laser light having passed through the beam splitter 16 enters the exposure apparatus 200.

### 1.3 Line Narrowing Module 14

### 1.3.1 Configuration

The prisms 41 to 43 are arranged in ascending order of the reference number thereof in the optical path of the light beam having exited via the window 10a. The prisms 41 to 43 are each so disposed that the surface thereof on which the light beam is incident and the surface thereof via which the light beam exits are both parallel to the V-axis. The prism 43 is rotatable around an axis parallel to the V-axis by a rotary stage 143.

The mirror 63 is disposed in the optical path of the light beam having passed through the prisms 41 to 43. The mirror 63 is so disposed that the surface thereof that reflects the light beam is parallel to the V-axis, and is rotatable around an axis parallel to the V-axis by a rotary stage 163.

The grating 53 is disposed in the optical path of the light beam reflected off the mirror 63. The direction of the grooves of the grating 53 is parallel to the V-axis.

### 1.3.2 Operation

The prisms 41 to 43 each redirect the light beam having exited via the window 10a in a plane parallel to the plane HZ, which is a plane perpendicular to the V-axis, and increase the width of the light beam in the plane parallel to the plane HZ.

The light beam having passed through the prisms 41 to 43 is reflected off the mirror 63 and incident on the grating 53.

The light beam incident on the grating 53 is reflected off and diffracted by the plural grooves of the grating 53 in the direction according to the wavelength of the light. The grating 53 is disposed in the Littrow arrangement, which causes the angle of incidence of the light beam incident from the mirror 63 on the grating 53 to be equal to the angle of diffraction of the diffracted light having the desired wavelength.

The mirror 63 and the prisms 41 to 43 reduce the beam width of the light beam having returned from the grating 53 in the plane parallel to the plane HZ, and cause the resultant light beam to return into the laser chamber 10 via the window 10a.

The laser control processor 130 controls the rotary stages 143 and 163 via drivers that are not shown. The angle of incidence of the light beam incident on the grating 53 changes in accordance with the angles of rotation of the rotary stages 143 and 163, and the wavelength selected by the line narrowing module 14 changes accordingly. The rotary stage 143 is used primarily for coarse adjustment, and the rotary stage 163 is used primarily for fine adjustment.

Based on the target long wavelength λL and the target short wavelength λS received from the exposure control processor 210, the laser control processor 130 controls the rotary stage 163 in such a way that the posture of the mirror 63 cyclically changes for each of plural pulses. The center wavelength of the pulse laser light thus cyclically changes from the target long wavelength λL to the target short wavelength λS and vice versa for each of the plural pulses. The laser apparatus 100 can thus perform laser oscillation at the plural wavelengths.

The focal length in the exposure apparatus 200 depends on the wavelength of the pulse laser light. The pulse laser light generated by the laser oscillation at the plural wavelengths and having entered the exposure apparatus 200 can form images at the plural different positions in the direction of the optical path axis of the pulse laser light, so that the depth of focus practically increases. For example, even when a photoresist film having a large thickness is exposed to the pulse laser light, the image formation performance can be maintained in the thickness direction of the photoresist film. Instead, a photoresist profile indicating the cross-sectional shape of the developed photoresist film can be adjusted.

### 1.4 Scanning Exposure

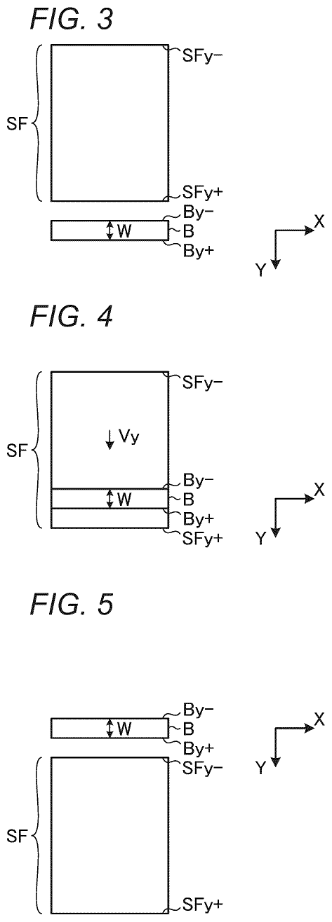

FIGS. 3 to 5 show how the position of a scan field SF of the photosensitive substrate changes with respect to the position of the pulse laser light. The photosensitive substrate is, for example, a single-crystal silicon plate having a substantially disk-like shape, and is coated, for example, with a photosensitive photoresist film. The scan field SF is, for example, a region where some of a large number of semiconductor chips formed in the photosensitive substrate are formed, and corresponds to the region where the mask pattern of a single mask is transferred in a single scan action. To expose one scan field SF to the pulse laser light, the pulse laser light is successively output at a predetermined repetition frequency. The successive output of the pulse laser light at a predetermined repetition frequency is called a burst output. To move the exposure position from a scan field SF to another, the output of the pulse laser light is paused. The burst output is therefore repeated multiple times to expose one photosensitive substrate to the pulse laser light.

The X-axis-direction width of the scan field SF corresponds to the X-axis-direction width of a beam cross-section B of the pulse laser light at the position of the workpiece table WT (see FIG. 1). The Y-axis-direction width of the scan field SF is greater than a Y-axis-direction width W of the beam cross-section B of the pulse laser light at the position of the workpiece table WT.

The procedure in which the scan field SF is scanned with and exposed to the pulse laser light is performed in the order of FIGS. 3, 4, and 5. First, the workpiece table WT is so positioned that an end SFy+ of the scan field SF, which is the end of the scan field SF in the +Y direction, is located at a position separate by a predetermined distance in the −Y direction from the position of an end By− of the beam cross-section B, which is the end in the −Y direction, as shown in FIG. 3. The workpiece table WT is then so accelerated in the +Y direction that the speed thereof reaches a speed Vy by the time when the end SFy+ of the scan field SF, which is the end of the scan field SF in the +Y direction, coincides with the position of the end By− of the beam cross-section B, which is the end of the beam cross-section B in the −Y direction. The scan field SF is exposed to the pulse laser light while the workpiece table WT is so moved in the +Y direction that the position of the scan field SF makes uniform linear motion at the speed Vy with respect to the position of the beam cross-section B, as shown in FIG. 4. The scanning of the scan field SF ends after the workpiece table WT is moved until an end SFy− of the scan field SF, which is the end of the scan field SF in the −Y direction, passes through the position of an end By+ of the beam cross-section B, which is the end of the beam cross-section B in the +Y direction, as shown in FIG. 5.

The exposure is thus performed while the scan field SF is moved with respect to the position of the beam cross-section B. It can be also said that the scan field SF is scanned with the pulse laser light in the −Y direction with reference to the scan field SF. The −Y direction corresponds to the first direction in the present disclosure.

A period Ts required for the scan field SF to move at the speed Vy over a distance corresponding to the width W of the beam cross-section B of the pulse laser light is shown below.

$$Ts = W / Vy$$

The number of pulses Ns of the pulse laser light radiated to any one location in the scan field SF is equal to the number of pulses of the pulse laser light generated in the required period Ts and is as follows:

$$Ns = F \cdot Ts$$

where F represents the repetition frequency of the pulse laser light.

The number of radiated pulses Ns is also referred to as the number of N slit pulses.

The scan field SF that is a portion of the photosensitive substrate for manufacturing electronic devices has been described above, and the same applies to the scan field SF that is a portion of a test wafer that will be described later.

### 1.5 Cyclic Wavelength Change and Accumulated Spectrum

FIG. 6 is a graph showing a cyclic change in wavelength. In FIG. 6, the horizontal axis represents time t, and the vertical axis represents a wavelength λ. The small circles shown in FIG. 6 each indicate the time t when the pulse laser light is output and the center wavelength thereof at the time t.

In the example shown in FIG. 6, the center wavelength cyclically changes between the target long wavelength λL and the target short wavelength λS. Let N be the number of pulses in one cycle of the change in the wavelength. A cycle T of the change in the wavelength is given by the expression below.

$$T = N / F$$

FIG. 7 shows an accumulated spectrum of the pulse laser light having plural center wavelengths. The accumulated spectrum shown in FIG. 7 corresponds to the accumulated spectrum for one cycle of the change in the wavelength shown in FIG. 6. In FIG. 7, the horizontal axis represents the wavelength λ, and the vertical axis represents light intensity I. The broken lines show each the spectrum of the pulse laser light on a pulse basis, and the center wavelength of each of the spectra may coincide with the peak wavelength. Changing the center wavelength in multiple steps between the target long wavelength λL and the target short wavelength λS as shown in FIG. 6 may allow the accumulated spectrum shown in FIG. 7 to have a flat-top shape having a substantially uniform light intensity I between the target long wavelength λL and the target short wavelength λS.

It is desirable that the number of pulses Ns of the pulse laser light radiated to any one location in the scan field SF is a multiple of the number of pulses N corresponding to one cycle of the change in the wavelength. Any portion of the scan field SF is thus irradiated with the pulse laser light including radiated pulses the number of which is Ns and each of which has the same accumulated spectrum. High-quality electronic devices can thus be so manufactured that the amount of exposure variation caused depending on the radiation position is small.

### 1.6 Optical Proximity Correction (OPC)

### 1.6.1 Overview

In photolithography, when the dimensions of a designed target pattern G are smaller than the wavelength of the light from a light source for exposure, drawing the target pattern G as it is onto a mask followed by exposure may not produce a wafer pattern comparable to the target pattern G. To avoid the situation described above, creating a corrected mask pattern F by correcting the target pattern G in advance to produce a wafer pattern comparable to the target pattern G is called optical proximity correction (OPC).

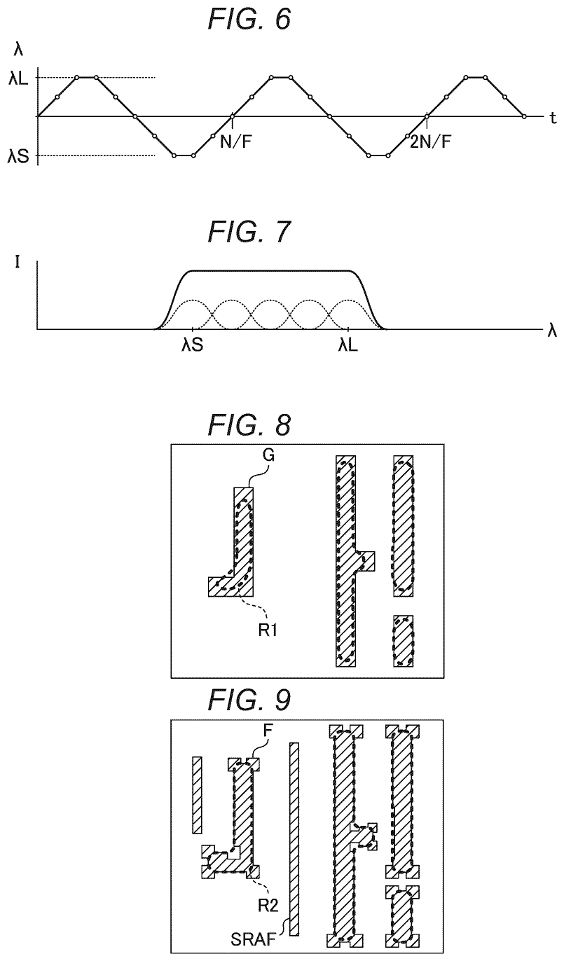

FIG. 8 shows an example in which a wafer pattern R1 different from the target pattern G is formed due to the optical proximity effect when the target pattern G is used as it is as the mask pattern. For example, the optical proximity effect may cause the corners contained in the target pattern G to be rounded in the wafer pattern R1, or a convex portion in the target pattern G to be retracted in the wafer pattern R1.

FIG. 9 shows an example in which a wafer pattern R2 close to the target pattern G is formed by using the corrected mask pattern F having undergone optical proximity correction. Creating the corrected mask pattern F includes, for example, deformation such as adding an overhang to a convex corner in the target pattern G, further recessing a concave corner in the target pattern G, or adding an auxiliary pattern called a sub-resolution assist feature (SRAF). The wafer pattern R2 having a shape close to the target pattern G can thus be produced.

In the optical proximity correction, not only can the shapes due to the optical proximity effect be corrected, but also differences between the mask pattern and the wafer pattern that occur in the photoresist film development and other semiconductor processes can be corrected at the same time.

Two types of optical proximity correction are known, model-based OPC and rule-based OPC. The two types of optical proximity correction will be described below.

### 1.6.2 Model-Based OPC

In the model-based OPC, a model function group M is created based on the result of an exposure simulation performed for each characteristic shape contained in the target pattern G and an actual exposure result. The corrected mask pattern F for producing a wafer pattern comparable to the target pattern G is created by using the model function group M. The model-based OPC is used primarily in linewidth generations smaller than 130 nm.

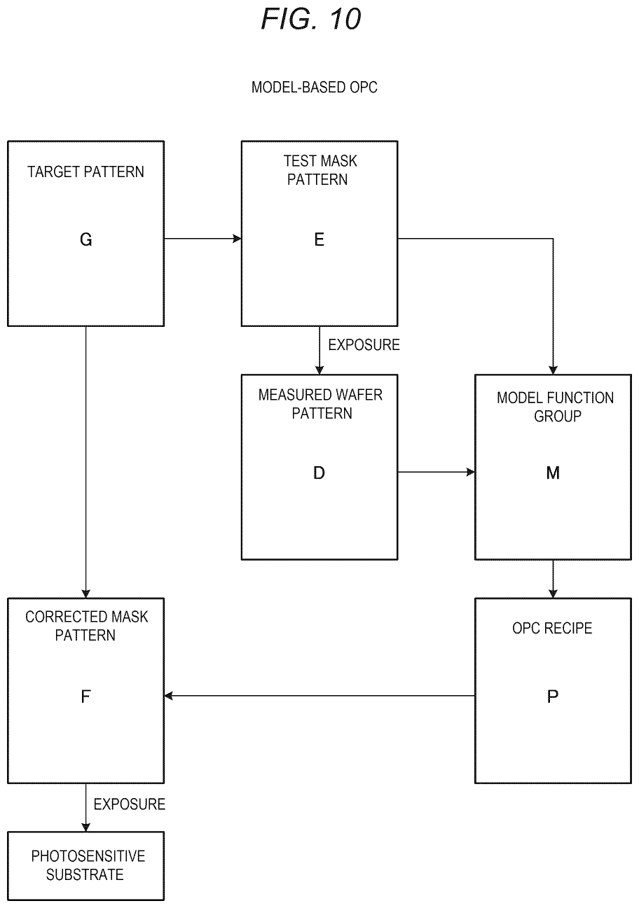

FIG. 10 is a conceptual view of model-based OPC in Comparative Example. A test mask having a test mask pattern E is first created based on the target pattern G. A test wafer is exposed to the pulse laser light by using the test mask, and the patterned test wafer is measured to acquire a measured wafer pattern D.

Based on the result of the exposure simulation using the test mask pattern E and the measured wafer pattern D, which is the result of the actual exposure, the model function group M for predicting the result of the actual exposure from the result of the exposure simulation is created. The thus created model function group M is used to create an OPC recipe P, which is a program for creating the corrected mask pattern F from the target pattern G. The corrected mask pattern F is created by executing the OPC recipe P using the target pattern G. A wafer pattern close to the target pattern G can be produced by exposing a photosensitive substrate to the pulse laser light with the corrected mask pattern F.

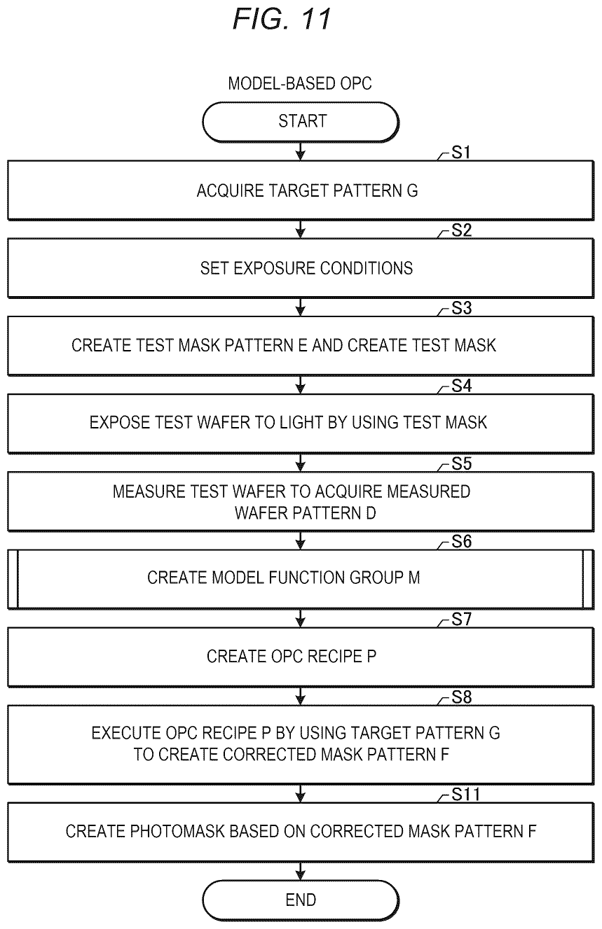

FIG. 11 is a flowchart of the model-based OPC. The processes shown in FIG. 11 are carried out primarily by a processor, such as the exposure control processor 210. The processor may be a component provided in another apparatus that is not shown, such as a mask manufacturing apparatus, and the configuration of such a processor may be the same as that of the exposure control processor 210.

In S1, the processor acquires the target pattern G. The target pattern G is a target wafer pattern designed for a photosensitive substrate by a semiconductor chip designer, and is provided, for example, in a data format called a graphic data system (GDS). The target pattern G may be a post-etching pattern in a case where the photosensitive substrate is etched, or the pattern of the photoresist film developed after the exposure in a case where the photosensitive substrate is not etched.

In S2, the processor sets exposure conditions based on the target pattern G. The exposure conditions include conditions under which the exposure apparatus 200 is set, for example, the shape of the illumination light source via the illumination optical system 201 (see FIG. 1), whether polarized illumination is used, and the numerical aperture of the projection optical system 202. The exposure conditions further include, for example, the type of the photoresist film, whether an antireflective film is present and the type of the antireflection if any, photoresist stack information, the photoresist film thickness, photoresist film application conditions, and development conditions.

In S3, the processor creates the test mask pattern E based on the target pattern G. Specifically, characteristic shapes contained in the target pattern G are extracted, and one or more dimensional conditions are set for each of the characteristic shapes to form the test mask pattern E.

A test mask is created by a mask manufacturing apparatus in accordance with the test mask pattern E.

In S4, the exposure apparatus 200 exposes the test wafer to the pulse laser light by scanning the test wafer via the test mask. The test wafer is a substrate which is used for test exposure and onto which a photoresist film is applied under the same conditions as those under which a photoresist film is applied onto the photosensitive substrate.

Furthermore, the test wafer is patterned by causing a developer that is not shown to develop the test wafer and, when the test wafer needs to be etched, causing an etching apparatus that is not shown to etch the test wafer.

In S5, the processor measures the wafer pattern of the test wafer with a measurement apparatus that is not shown, such as a CD-SEM, and acquires the measured wafer pattern D showing the result of the measurement.

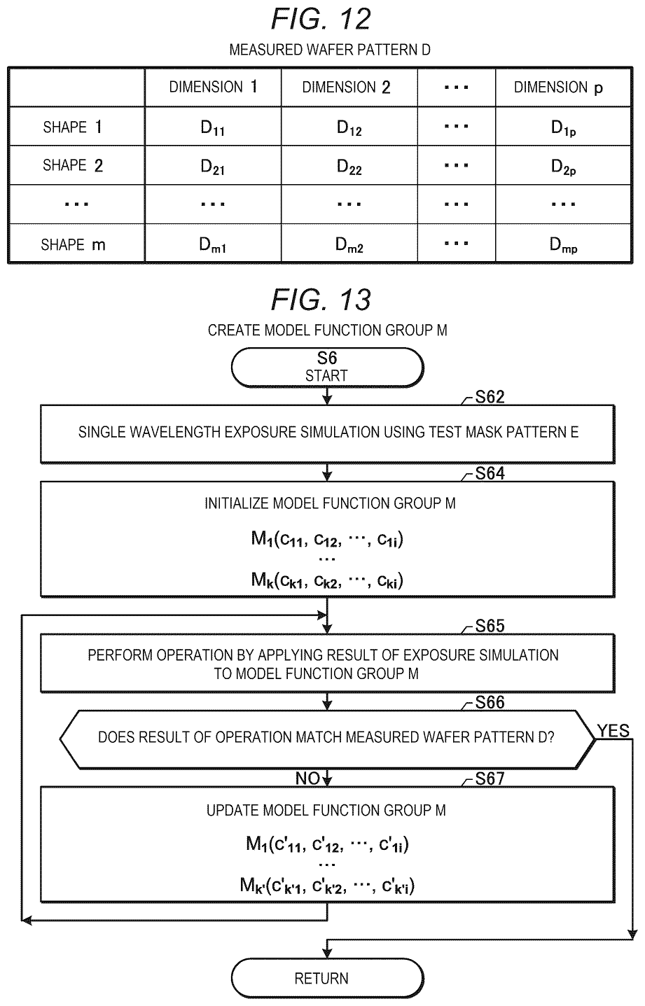

FIG. 12 shows the structure of data on the measured wafer pattern D. The measured wafer pattern D contains p measured dimensions of each of m shapes 1 to m. For example, dimensions D₁₁ to D₁ₚ of the shape 1 are measured, dimensions D₂₁ to D₂ₚ of the shape 2 are measured, and dimensions Dₘ₁ to Dₘₚ of the shape m are measured. Note that the values of p for the shapes 1 to m may differ from one another, and the values of p may each be 1, 2, or greater.

When plural scan fields SF of the test wafer are exposed as a test to the pulse laser light via a single test mask, the average value for each of the shapes and dimensions is calculated from the results of the measurement of the plural scan fields SF to provide the measured wafer pattern D.

Referring again to FIG. 11, the processor creates in S6 the model function group M based on the test mask pattern E and the measured wafer pattern D.

FIG. 13 is a flowchart showing the processes of creating the model function group M in detail. The processes shown in FIG. 13 correspond to the subroutine labeled with step S6 in FIG. 11.

In S62, the processor performs a single wavelength exposure simulation using the test mask pattern E. Fourier's imaging theory is used in the exposure simulation.

In S64, the processor performs initialization of the model function group M. The model function group M includes, for example, k functions M₁ to Mₖ. The functions M₁ to Mₖ each contains plural coefficients. For example, the function M₁ contains i coefficients c₁₁ to c₁ᵢ, and the function Mₖ contains i coefficients cₖ₁ to cₖᵢ. Note that the values of i for the functions M₁ to Mₖ may differ from one another.

In S65, the processor performs operation of predicting the wafer pattern by applying the result of the exposure simulation to the model function group M. The predictive operation includes the four basic arithmetic operations and convolutional integration.

In S66, the processor evaluates whether the result of the prediction operation matches the measured wafer pattern D. Even when the result of the predictive operation does not exactly match the measured wafer pattern D, the processor can determine that the result of the predictive operation matches the measured wafer pattern D as long as predetermined conditions are satisfied. When the result of the predictive operation matches the measured wafer pattern D (YES in S66), the processor sets the model function group M used in S65 as the created model function group M, terminates the processes in the present flowchart, and returns to the processes shown in FIG. 11. When the result of the predictive operation does not match the measured wafer pattern D (NO in S66), the processor proceeds to the process in S67.

In S67, the processor updates the model function group M by changing the coefficients contained in the model function group M or performing other modifications. The updated model function group M includes, for example, k′ functions M₁ to M_{k′}. The value of k′, which indicates the number of functions M₁ to Mₖ, may differ from the number of functions M₁ to Mₖ contained in the model function group M used in S65. Coefficients c′₁₁ to c′_{k′i} contained in the functions M₁ to M_{k′} may also differ from the coefficients c₁₁ to cₖᵢ contained in the model function group M used in S65.

After S67, the processor returns to the process in S65 to update the model function group M until the result of the predictive operation matches the measured wafer pattern D.

Referring again to FIG. 11, the processor creates in S7 the OPC recipe P based on the model function group M. The OPC recipe P includes, for example, the definition of the model function group M, the points where and the directions in which the dimensions D₁₁ to Dₘₚ shown in FIG. 12 are measured, and a description of the mask pattern correction rules.

In S8, the processor executes the OPC recipe P by using the target pattern G to create the corrected mask pattern F. The corrected mask pattern F is also provided in the GDS data format.

In S11, the mask manufacturing apparatus creates a photomask based on the corrected mask pattern F, and the processes in the present flowchart end.

### 1.6.3 Rule-Based OPC

In the rule-based OPC, correction rules are determined in advance in accordance with the dimensions of the shapes contained in the target pattern G and the distances from the shapes to other shapes, and the corrected mask pattern F is created from the target pattern G in accordance with the rules. The rule-based OPC is less computationally intensive and faster, but has accuracy lower than that of the model-based OPC, and is used primarily for linewidth generations up to around 130 nm.

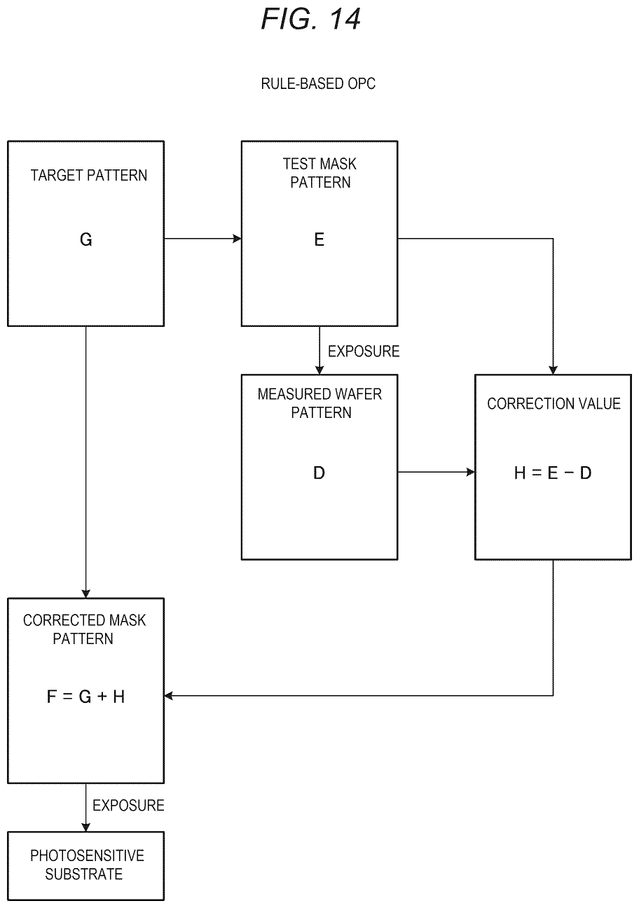

FIG. 14 is a conceptual view of the rule-based OPC in Comparative Example. The rule-based OPC is the same as the model-based OPC in that a test wafer is exposed to the pulse laser light by using a test mask containing the test mask pattern E created based on the target pattern G, and that the patterned test wafer is measured to acquire the measured wafer pattern D.

In the rule-based OPC, a correction value His calculated based on the amount of deviation of the measured wafer pattern D, which is the result of the actual exposure, from the test mask pattern E. Although the correction value H is not necessarily the simple difference between the test mask pattern E and the measured wafer pattern D, the difference between the test mask pattern E and the measured wafer pattern D is used as the correction value H for conceptually clear description.

The corrected mask pattern F is created by adding the correction value H to the target pattern G. A wafer pattern close to the target pattern G can be produced by exposing a photosensitive substrate to the pulse laser light with the corrected mask pattern F.

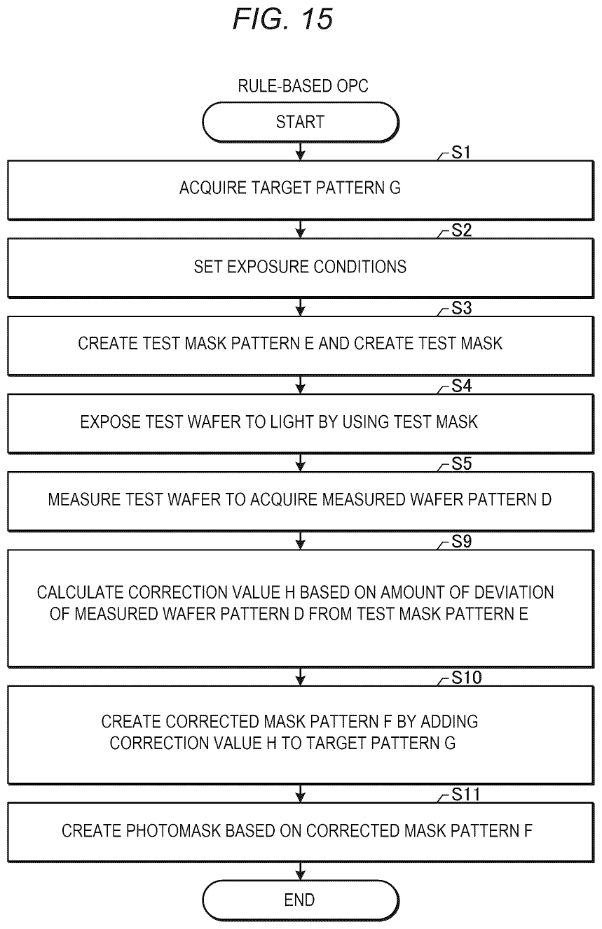

FIG. 15 is a flowchart of the rule-based OPC. The processes shown in FIG. 15 are carried out primarily by the processor.

The processes from S1 to S5 and S11 are the same as the processes in the model-based OPC described with reference to FIG. 11.

In S9, the processor calculates the correction value H based on the amount of deviation of the measured wafer pattern D from the test mask pattern E.

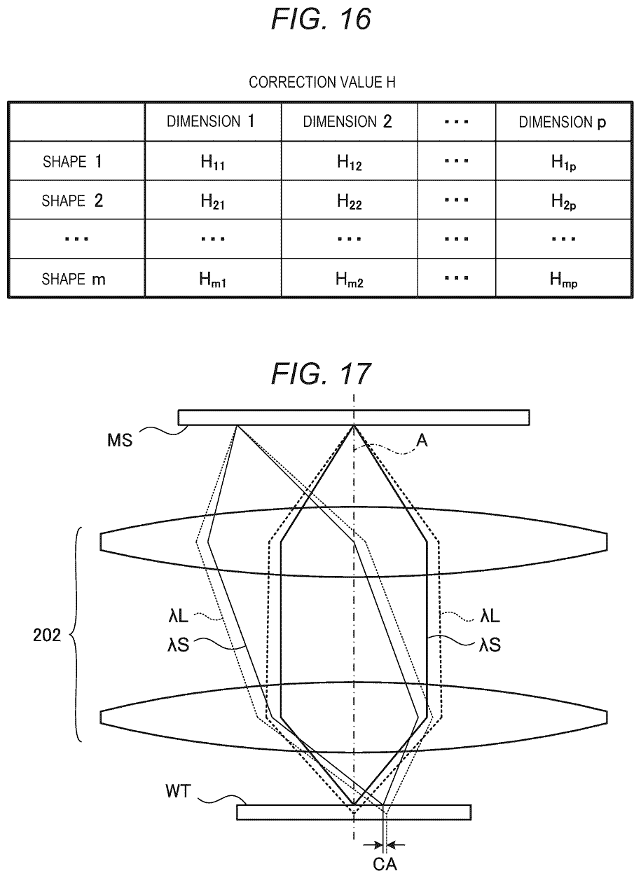

FIG. 16 shows the structure of data on the correction value H. The correction value H contains correction values corresponding to the p measured dimensions of each of the m shapes 1 to m. For example, correction values H₁₁ to H₁ₚ are calculated for the shape 1, correction values H₂₁ to H₂ₚ are calculated for the shape 2, and correction values Hₘ₁ to Hₘₚ are calculated for the shape m. Note that the values of p for the shapes 1 to m may differ from one another, and the values of p may each be 1, 2, or greater.

Referring again to FIG. 15, the processor creates in S10 the corrected mask pattern F by adding the correction value H to the target pattern G.

Regarding the other points, the rule-based OPC is the same as the model-based OPC.

1.7 Problems with Comparative Example

FIG. 17 shows the concept of an off-axis chromatic aberration CA produced when the photosensitive substrate is exposed to the pulse laser light having the plural wavelengths. As shown in FIG. 17, since the refractive index of the projection optical system 202 at the target long wavelength λL and the target short wavelength λS differ from each other, a portion of the mask pattern of the mask placed on the mask stage MS, the portion located in an optical path axis A of the projection optical system 202, is brought into focus at different positions in the depth direction of the photosensitive substrate placed on the workpiece table WT. The difference is called an axial chromatic aberration. In contrast, the portions of the mask pattern that are located away from the optical path axis A are brought into focus at different positions not only in the depth direction of the photosensitive substrate but in the plane direction of the photosensitive substrate. The latter difference is called the off-axis chromatic aberration CA.

When the photosensitive substrate is exposed to the pulse laser light having the plural wavelengths, the images are formed at different positions in the plane direction of the photosensitive substrate due to the differences in wavelengths, so that a wafer pattern close to the target pattern G may not be produced even when a mask pattern having undergone the related-art optical proximity correction is used. It is conceivable to reflect the off-axis chromatic aberration CA on a wavelength basis by calculating the image formation position, but performing the optical proximity correction on a wavelength basis could result in an enormous amount of computation.

### 2. Divided-Model-Based OPC

### 2.1 Operation

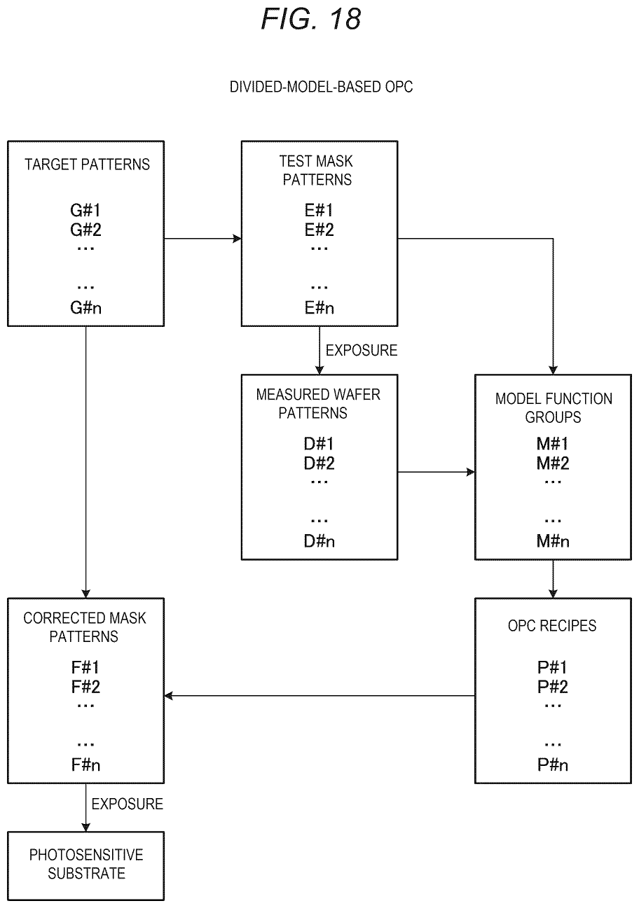

FIG. 18 is a conceptual view of divided-model-based OPC in a first embodiment. The divided-model-based OPC differs from the model-based OPC in Comparative Example in that the target pattern G, the test mask pattern E, the measured wafer pattern D, the model function group M, the OPC recipe P, and the corrected mask pattern F are each created for each of plural divided regions #1 to #n and the model-based OPC is performed for each of the divided regions #1 to #n.

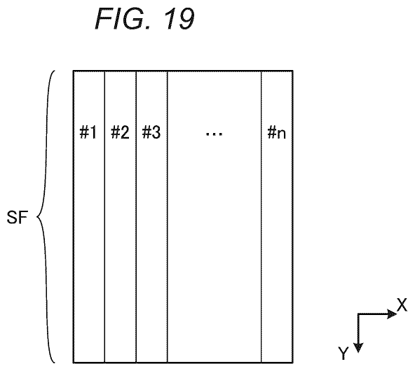

FIG. 19 shows the plural divided regions #1 to #n contained in the scan field SF of the test wafer. The symbol n is an integer greater than or equal to two, and the plural divided regions #1, #2, . . . , and #n are arranged in this order in a slit direction that intersects with the −Y direction on the surface of the test wafer. The slit direction is, for example, the X-axis direction perpendicular to the −Y direction, and corresponds to the second direction in the present disclosure. The widths of the divided regions #1 to #n in the slit direction are desirably equal to one another. The number of divided regions #1 to #n, that is, the value of n is desirably greater than or equal to three but smaller than or equal to fifteen.

Referring again to FIG. 18, the measured wafer pattern D acquired from the scan field SF of the test wafer is segmented into measured wafer patterns D #1 to D #n in correspondence with the divided regions #1 to #n.

One scan field SF contained in the test wafer corresponds to the region where the test mask pattern E formed at one test mask is transferred in one scan action, and is in correspondence with the test mask. The test mask pattern E is also segmented into test mask patterns E #1 to E #n in correspondence with the divided regions #1 to #n.

One scan field SF contained in the test wafer is in correspondence with one scan field SF contained in a photosensitive substrate. The target pattern G to be formed at the photosensitive substrate is also segmented into target patterns G #1 to G #n in correspondence with the divided regions #1 to #n.

One scan field SF contained in the photosensitive substrate corresponds to the region where the corrected mask pattern F of one photomask is transferred in one scan action, and is in correspondence with the photomask. The corrected mask pattern F is also segmented into corrected mask patterns F #1 to F #n in correspondence with the divided regions #1 to #n.

In the divided-model-based OPC, model function groups M #1 to M #n corresponding to the divided regions #1 to #n are created, and OPC recipes P #1 to P #n corresponding to the divided regions #1 to #n are created.

One of the divided regions #1 to #n in the first embodiment corresponds to the first divided region in the present disclosure, and another corresponds to the second divided region in the present disclosure.

In the first embodiment, for example, when it is assumed that the divided region #1 corresponds to the first divided region in the present disclosure, the measured wafer pattern D #1 corresponds to the first measured wafer pattern in the present disclosure, the test mask pattern E #1 corresponds to the first test mask pattern in the present disclosure, the target pattern G #1 corresponds to the first target pattern in the present disclosure, the corrected mask pattern F #1 corresponds to the first corrected mask pattern in the present disclosure, and the model function group M #1 corresponds to the first model function in the present disclosure.

When it is assumed that the divided region #2 corresponds to the second divided region in the present disclosure, the measured wafer pattern D #2 corresponds to the second measured wafer pattern in the present disclosure, the test mask pattern E #2 corresponds to the second test mask pattern in the present disclosure, the target pattern G #2 corresponds to the second target pattern in the present disclosure, the corrected mask pattern F #2 corresponds to the second corrected mask pattern in the present disclosure, and the model function group M #2 corresponds to the second model function in the present disclosure.

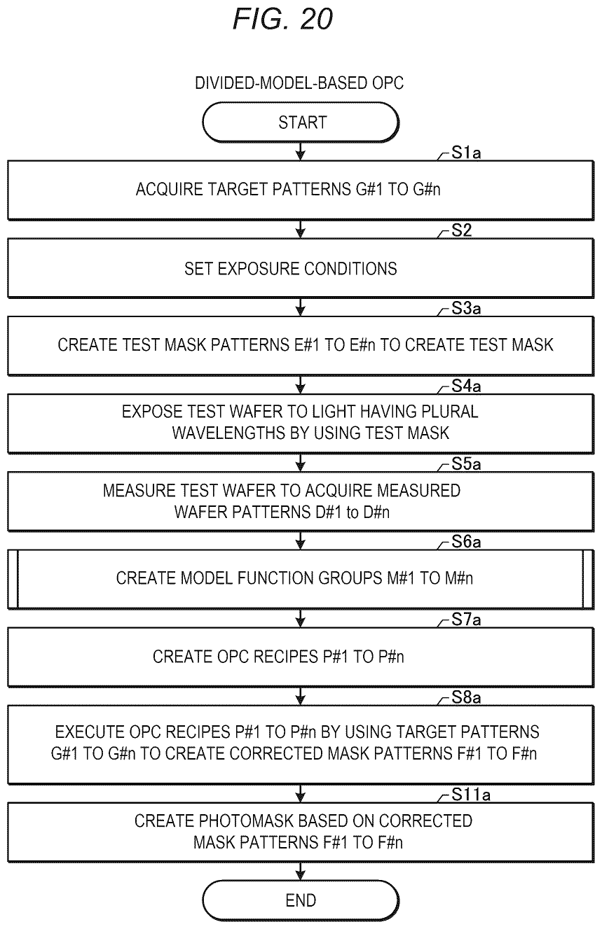

FIG. 20 is a flowchart of the divided-model-based OPC. The processes shown in FIG. 20 are carried out primarily by a processor, such as the exposure control processor 210.

In S1a, the processor acquires the target patterns G #1 to G #n. For example, the target patterns G #1 to G #n are acquired by dividing the target pattern G designed by the semiconductor chip designer into the divided regions #1 to #n.

The process in S2 is the same as the process in the model-based OPC described with reference to FIG. 11.

In S3a, the processor creates the test mask patterns E #1 to E #n based on the target patterns G #1 to G #n. Different test mask patterns E #1 to E #n may be created in accordance with the divided regions #1 to #n, for example, the test mask pattern E #1 is created based on characteristic shapes contained in the target pattern G #1, the test mask pattern E #2 is created based on characteristic shapes contained in the target pattern G #2, and so on. Instead, the test mask patterns E #1 to E #n each containing a common test mask pattern, that is, a pattern having the same shape may be created based on the characteristic shapes contained in the target patterns G #1 to G #n.

A test mask is created by the mask manufacturing apparatus in accordance with the test mask patterns E #1 to E #n.

In S4a, the exposure apparatus 200 exposes the test wafer to the pulse laser light by scanning the test wafer via the test mask. The test wafer is exposed to the light having the plural wavelengths used for the exposure of the photosensitive substrate.

Furthermore, the test wafer is patterned by causing a developer that is not shown to develop the test wafer and, when the test wafer needs to be etched, causing an etching apparatus that is not shown to etch the test wafer.

In S5a, the processor measures the wafer pattern of the test wafer, and acquires the measured wafer patterns D #1 to D #n showing the result of the measurement in the plural divided regions #1 to #n.

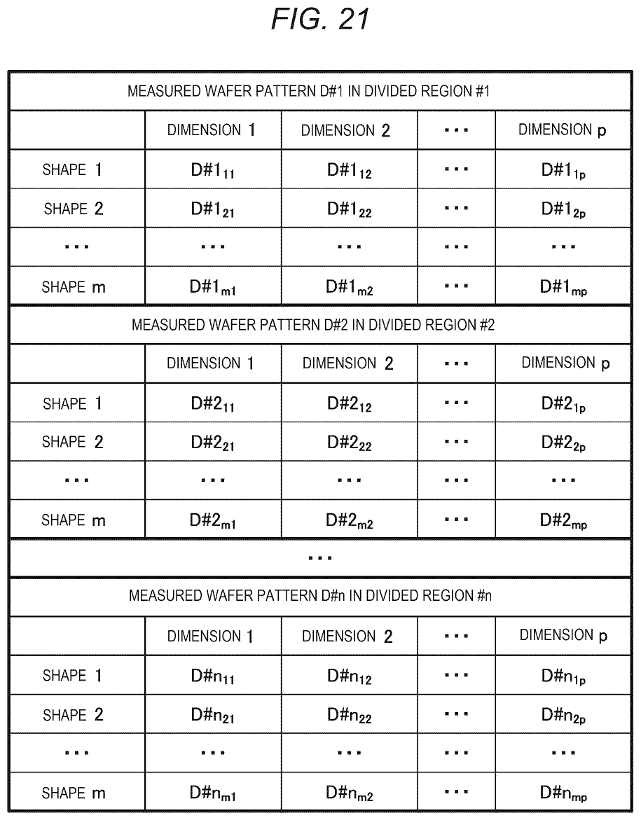

FIG. 21 shows the structures of data on the measured wafer patterns D #1 to D #n. The measured wafer patterns D #1 to D #n each contain the p measured dimensions of each of the m shapes 1 to m.

When plural scan fields SF of the test wafer are exposed as a test to the pulse laser light via a single test mask, the average value for each of the divided regions, the shapes, and the dimensions is calculated from the results of the measurement of the plural scan fields SF to provide the measured wafer patterns D #1 to D #n.

Referring again to FIG. 20, the processor creates in S6a the model function groups M #1 to M #n based on the test mask patterns E #1 to E #n and the measured wafer patterns D #1 to D #n, respectively. For example, the model function group M #1 is created based on the test mask pattern E #1 and the measured wafer pattern D #1, and the model function group M #2 is created based on the test mask pattern E #2 and the measured wafer pattern D #2.

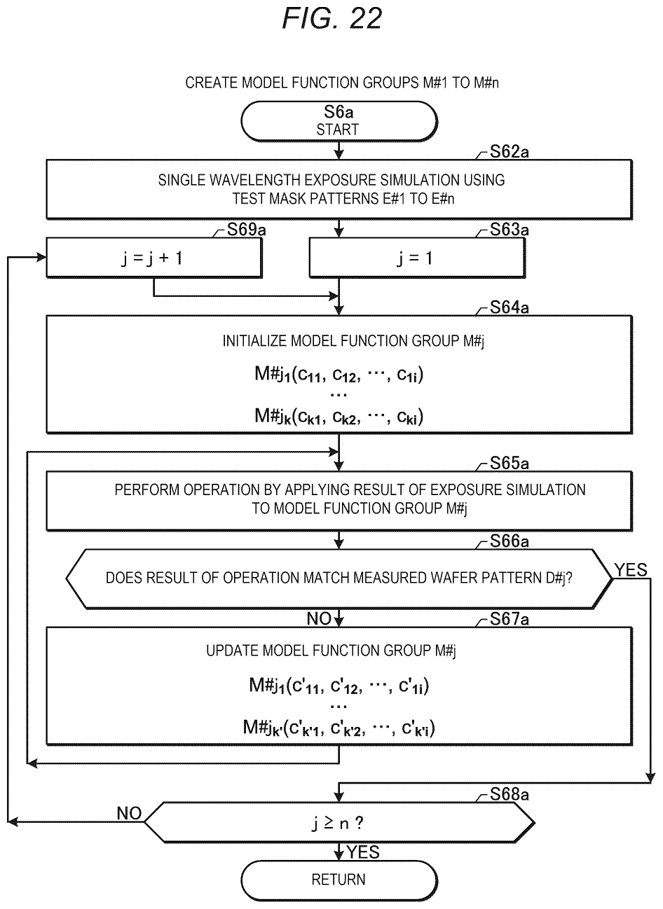

FIG. 22 is a flowchart showing the processes of creating the model function groups M #1 to M #n in detail. The processes shown in FIG. 22 correspond to the subroutine labeled with step S6a in FIG. 20.

In S62a, the processor performs an exposure simulation using the test mask patterns E #1 to E #n. The exposure simulation may be performed with light having fewer center wavelengths than the pulse laser light having the plural center wavelengths with which the test wafer is scanned. The exposure simulation is desirably performed at a single wavelength.

In S63a, the value of a counter j is set at an initial value of 1. The counter j identifies one of the model function groups M #1 to M #n, one of the test mask patterns E #1 to E #n, and one of the measured wafer patterns D #1 to D #n.

The processes in steps S64a to S67a are the same as the processes in steps S64 to S67 described with reference to FIG. 13. However, one of the model function groups M #1 to M #n that is identified by the counter j is created by using the result of the exposure simulation using one of the test mask patterns E #1 to E #n that is identified by the counter j and one of the measured wafer patterns D #1 to D #n that is identified by the counter j. When the result of the evaluation in S66a is YES, and one of the model function groups M #1 to M #n is created, the processor proceeds to the process in S68a.

In S68a, the processor evaluates whether the value of the counter j is greater than or equal to n. When the value of the counter j is smaller than n (NO in S68a), the processor adds one to the value of the counter j in S69a, and returns to the process in S64a to set a model function group M #j for another divided region. When the value of the counter j is greater than or equal to n, the processor terminates the processes in the present flowchart and returns to the processes shown in FIG. 20.

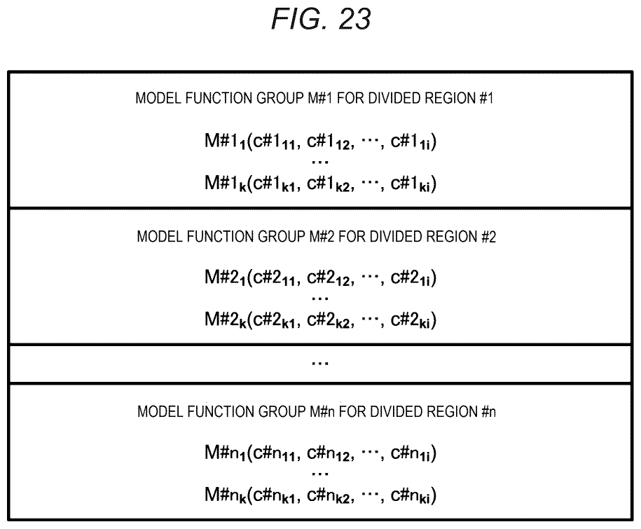

FIG. 23 shows an example of the model function groups M #1 to M #n. When one of the model function groups M #1 to M #n is identified by j, the one model function group M #j contains k functions M #j₁ to M #jₖ. The number of functions M #j₁ to M #jₖ, that is, the value of k, may vary among the model function groups M #1 to M #n.

Referring again to FIG. 20, the processor creates in S7a the OPC recipes P #1 to P #n based on the model function groups M #1 to M #n, respectively.

In S8a, the processor executes the OPC recipes P #1 to P #n by using the target patterns G #1 to G #n, respectively, to create the corrected mask patterns F #1 to F #n. The processor thus creates, for example, the corrected mask pattern F #1 based on the target pattern G #1 and the model function group M #1, and the corrected mask pattern F #2 based on the target pattern G #2 and the model function group M #2.

In S11a, the mask manufacturing apparatus creates a photomask based on the corrected mask patterns F #1 to F #n and the processes in the present flowchart end.

### 2.2 Effects

(1) According to the method for creating a photomask used for photolithography in the first embodiment, a test wafer is patterned by scanning the test wafer via the test mask in the −Y direction with the pulse laser light having the plural center wavelengths.

The wafer pattern of the patterned test wafer is measured to acquire the measured wafer patterns D #1 to D #n on the surface of the test wafer, which indicate the results of the measurement in the plural divided regions #1 to #n arranged in the slit direction, which intersects with the −Y direction.

The corrected mask patterns F #1 to F #n for creating the photomask are created based on the test mask patterns E #1 to E #n formed at the test mask, the measured wafer patterns D #1 to D #n, and the target patterns G #1 to G #n, which are target wafer patterns at the photosensitive substrate.

The photomask is then created based on the corrected mask patterns F #1 to F #n.

The corrected mask patterns F #1 to F #n can thus be created by using the results of the measurement in the divided regions #1 to #n to perform the optical proximity correction in consideration of the off-axis chromatic aberration in the slit direction.
(2) According to the first embodiment, the model function groups M #1 to M #n for predicting the measured wafer patterns D #1 to D #n from the test mask patterns E #1 to E #n are created based on the test mask patterns E #1 to E #n and the measured wafer patterns D #1 to D #n.

The corrected mask patterns F #1 to F #n are created based on the target patterns G #1 to G #n and the model function groups M #1 to M #n.

The corrected mask patterns F #1 to F #n can thus be created by using the model functions to perform highly accurate optical proximity correction.
(3) According to the first embodiment, the model function groups M #1 to M #n are created by using the test mask patterns E #1 to E #n to perform the exposure simulation using the light having fewer center wavelengths than those of the pulse laser light having the plural center wavelengths with which the test wafer is scanned.

In the first embodiment, scanning the test wafer with the pulse laser light having the plural center wavelengths causes the measured wafer patterns D #1 to D #n to reflect the off-axis chromatic aberration. The number of center wavelengths can thus be reduced in the exposure simulation for creating the model function groups M #1 to M #n to reduce the computational load.
(4) According to the first embodiment, the plural model function groups M #1 to M #n are created for the respective divided regions #1 to #n.

The corrected mask patterns F #1 to F #n can therefore be created by creating the model function groups M #1 to M #n for the respective divided regions #1 to #n and performing the optical proximity correction in consideration of the off-axis chromatic aberration in the slit direction. The amount of computation required to create the model function groups M #1 to M #n depends on the areas of the test mask and the test wafer. Even when the model function groups M #1 to M #n are created on a divided region basis, the areas of the test mask and the test wafer remain the same, so that the amount of computation does not increase but is comparable to that required to create the model function group M in Comparative Example.
(5) According to the first embodiment, the measured wafer patterns D #1 to D #n include the first measured wafer pattern D #1 in the first divided region #1 out of the plural divided regions #1 to #n, and the second measured wafer pattern D #2 in the second divided region #2 out of the plural divided regions #1 to #n.

The test mask patterns E #1 to E #n include the first test mask pattern E #1 in the portion of the test mask that corresponds to the first divided region #1, and the second test mask pattern E #2 in the portion of the test mask that corresponds to the second divided region #2.

The model function groups M #1 to M #n include the first model function group M #1, which is created for the first divided region #1, and the second model function group M #2, which is created for the second divided region #2.

The first model function group M #1 is created based on the first test mask pattern E #1 and the first measured wafer pattern D #1, and the second model function group M #2 is created based on the second test mask pattern E #2 and the second measured wafer pattern D #2.

The optical proximity correction in consideration of the off-axis chromatic aberration in the slit direction can therefore be performed by creating the first model function group M #1 using the first test mask pattern E #1 and the first measured wafer pattern D #1 corresponding to the first divided region #1, and by creating the second model function group M #2 using the second test mask pattern E #2 and the second measured wafer pattern D #2 corresponding to the second divided region #2.
(6) According to the first embodiment, the first test mask pattern E #1 and the second test mask pattern E #2 each contain a pattern having the same shape.

Therefore, the test mask is readily manufactured, and the test wafer is readily measured, so that the data are readily handled.
(7) According to the first embodiment, the plural divided regions #1 to #n include the first divided region #1 and the second divided region #2.
The target patterns G #1 to G #n include the first target pattern G #1 in the portion of the photosensitive substrate that corresponds to the first divided region #1, and the second target pattern G #2 in the portion of the photosensitive substrate that corresponds to the second divided region #2.
The corrected mask patterns F #1 to F #n include the first corrected mask pattern F #1 in the portion of the photomask that corresponds to the first divided region #1, and the second corrected mask pattern F #2 in the portion of the photomask that corresponds to the second divided region #2.

The first corrected mask pattern F #1 is created based on the first target pattern G #1 and the first model function group M #1, and the second corrected mask pattern F #2 is created based on the second target pattern G #2 and the second model function group M #2.

The first corrected mask pattern F #1 and the second corrected mask pattern F #2 can thus be created by using the first model function group M #1, the second model function group M #2, the first target pattern G #1, and the second target pattern G #2 to perform the optical proximity correction in consideration of the off-axis chromatic aberration in the slit direction.

As for the other points, the first embodiment is the same as the model-based OPC in Comparative Example.

### 3. Common-Model-Based OPC

### 3.1 Operation

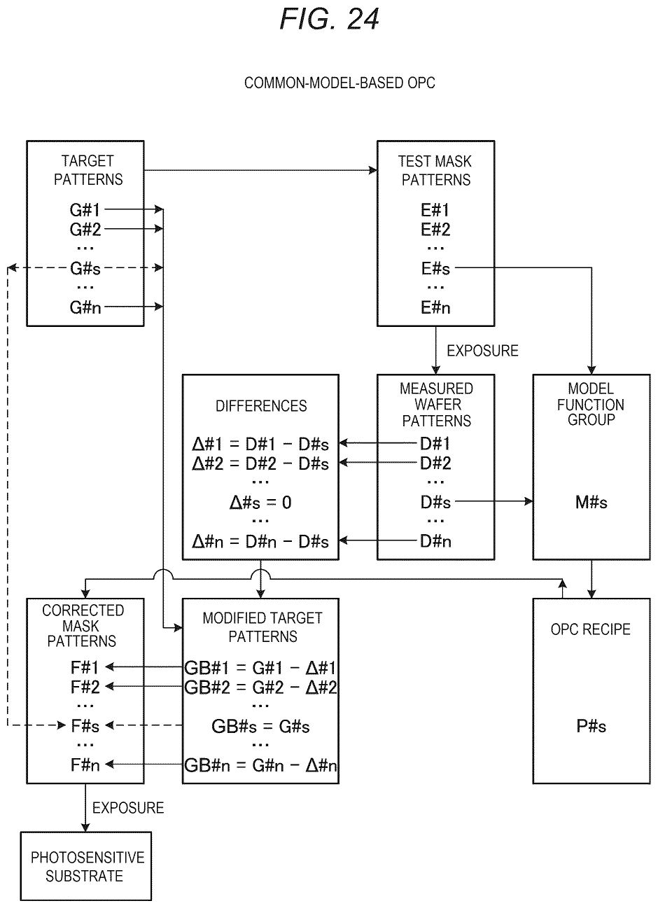

FIG. 24 is a conceptual view of common-model-based OPC in a second embodiment. The common-model-based OPC differs from the divided-model-based OPC in the first embodiment in that the number of model function groups M #s and OPC recipes P #s to be created is smaller than the number n of divided regions #1 to #n. The number of model function groups M #s and OPC recipes P #s to be created may be one.

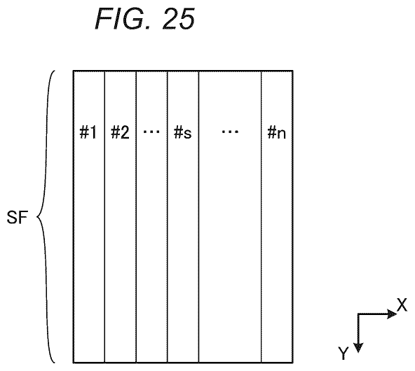

FIG. 25 shows the plural divided regions #1 to #n contained in the scan field SF of the test wafer. The divided regions #1 to #n include a divided region #s. The symbol s is an integer greater than or equal to 1 but smaller than or equal to n. In the second embodiment, the divided region #s may be referred to as a first divided region #s, and one of the divided regions #1 to #(s−1) and #(s+1) to #n other than the first divided region #s may be referred to as a second divided region. The first divided region #s is desirably closer to the center of the scan field SF in the slit direction than the second divided regions #1 to #(s−1) and #(s+1) to #n. For example, when n is an odd number, the first divided region #s may be located at the center of the scan field SF with s expressed by (n+1)/2.

Referring again to FIG. 24, the model function group M #s is created based on the test mask pattern E #s in the first divided region #s and the measured wafer pattern D #s in the first divided region #s. The OPC recipe P #s is created based on the model function group M #s.

Differences Δ #1 to Δ #n between the measured wafer patterns D #1 to D #n and the measured wafer pattern D #s are calculated, and modified target patterns GB #1 to GB #n are created by modifying the target patterns G #1 to G #n based on the differences Δ #1 to Δ #n, respectively.

The corrected mask patterns F #1 to F #n are created by executing the OPC recipe P #s by using the modified target patterns GB #1 to GB #n. Note that since the modified target pattern GB #s is the same as the target pattern G #s, executing the OPC recipe P #s using the modified target pattern GB #s is the same as executing the OPC recipe P #s using the target pattern G #s.

The measured wafer pattern D #s in the second embodiment corresponds to the first measured wafer pattern in the present disclosure, and one of the measured wafer patterns D #1 to D #(s−1) and D #(s+1) to D #n corresponds to the second measured wafer pattern in present disclosure.

The test mask pattern E #s in the second embodiment corresponds to the first test mask pattern in the present disclosure, and one of the test mask patterns E #1 to E #(s−1) and E #(s+1) to E #n corresponds to the second test mask pattern in present disclosure.

The target pattern G #s in the second embodiment corresponds to the first target pattern in the present disclosure, and one of the target patterns G #1 to G #(s−1) and G #(s+1) to G #n corresponds to the second target pattern in present disclosure.

The corrected mask pattern F #s in the second embodiment corresponds to the first corrected mask pattern in the present disclosure, and one of the corrected mask patterns F #1 to F #(s−1) and F #(s+1) to F #n corresponds to the second corrected mask pattern in present disclosure.

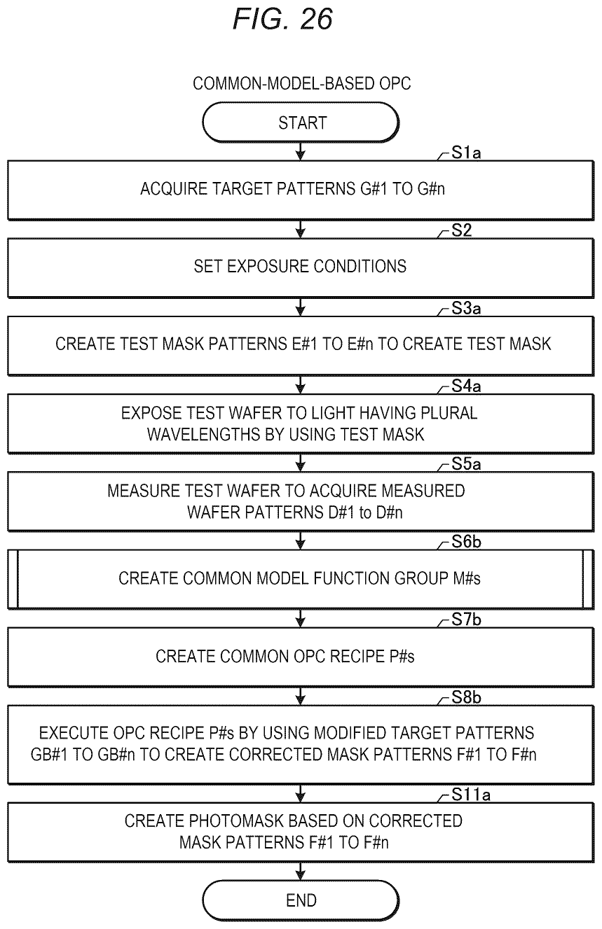

FIG. 26 is a flowchart of the common-model-based OPC. The processes shown in FIG. 26 are carried out primarily by a processor, such as the exposure control processor 210.

The processes from S1a to S5a are the same as the processes in the divided-model-based OPC described with reference to FIG. 20. Note, however that in S3a in FIG. 26, the test mask patterns E #1 to E #n desirably contain the same pattern, but not necessarily. When the test mask patterns E #1 to E #n contain the same pattern, the differences Δ #1 to Δ #n between the measured wafer patterns D #1 to D #n and the measured wafer pattern D #s can be directly used as the differences resulting from the off-axis chromatic aberration to create the modified target patterns GB #1 to GB #n. When the test mask patterns E #1 to E #n do not contain the same pattern, a portion resulting from the off-axis chromatic aberration is extracted from each of the differences Δ #1 to Δ #n.

In S6b, the processor creates the model function group M #s common to the divided regions #1 to #n based on the test mask pattern E #s and the measured wafer pattern D #s.

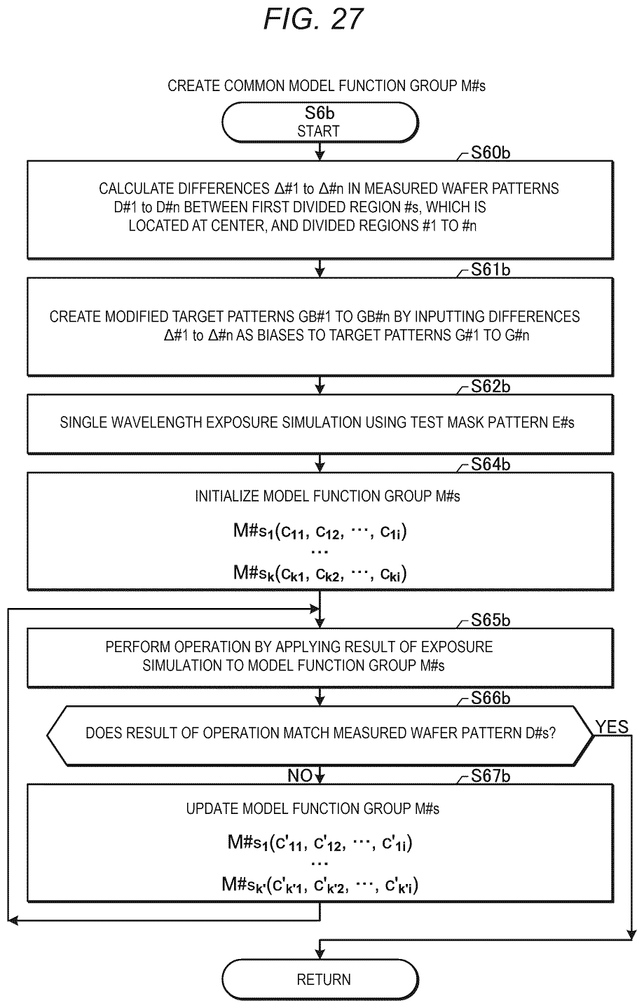

FIG. 27 is a flowchart showing the process of creating the model function group M #s in detail. The processes shown in FIG. 27 correspond to the subroutine labeled with step S6b in FIG. 26.

In S60b, the processor calculates the differences Δ #1 to Δ #n in the measured wafer patterns D #1 to D #n between the first divided region #s, which is located at or near the center of the scan field SF in the slit direction, and the divided regions #1 to #n.

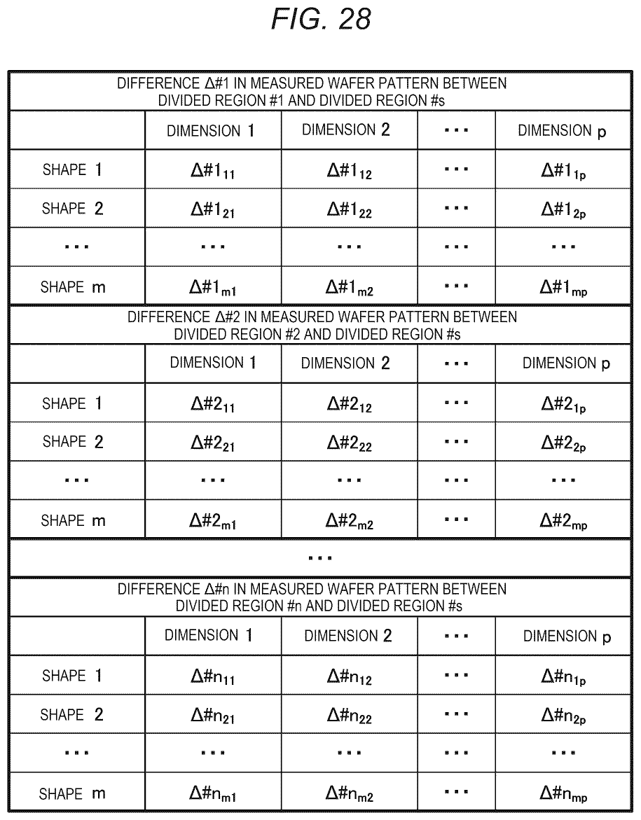

FIG. 28 shows the structure of data on the differences Δ #1 to Δ #n. The differences Δ #1 to Δ #n each contain differences corresponding to the p measured dimensions of each of the m shapes 1 to m. For example, the difference Δ #1 includes differences Δ #1₁₁ to Δ #1ₘₚ, the difference Δ #2 includes differences Δ #2₁₁ to Δ #2ₘₚ, and the difference Δ #n includes differences Δ #n₁₁ to Δ #nₘₚ. The differences Δ #s₁₁ to Δ #sₘₚ contained in the difference Δ #s are, although not shown, all zero.

Referring again to FIG. 27, the processor creates in S61b the modified target patterns GB #1 to GB #n by inputting the differences Δ #1 to Δ #n as biases to the target patterns G #1 to G #n, respectively.

The processes in steps S62b to S67b are the same as the processes in steps S62 to S67 described with reference to FIG. 13. However, the common model function group M #s is created by using the result of the exposure simulation using the test mask pattern E #s and the measured wafer pattern D #s. The measured wafer patterns D #1 to D #(s−1) and D #(s+1) to D #n other than the measured wafer pattern D #s may not be used to create the model function group. When the result of the evaluation in S66b is YES, and the model function group M #s is created, the processor terminates the processes in the present flowchart and returns to the processes shown in FIG. 26.

Referring again to FIG. 26, the processor creates in S7b the OPC recipe P #s common to the divided regions #1 to #n based on the model function group M #s.

In S8b, the processor executes the OPC recipe P #s by using the modified target patterns GB #1 to GB #n to create the corrected mask patterns F #1 to F #n, respectively.

The process in S11a is the same as the process in the divided-model-based OPC described with reference to FIG. 20. After S11a, the processor terminates the processes in the present flowchart.

### 3.2 Effects

(8) According to the second embodiment, the measured wafer patterns D #1 to D #n include the first measured wafer pattern D #s in the first divided region #s out of the plural divided regions #1 to #n, and the second measured wafer patterns D #1 to D #(s−1) and D #(s+1) to D #n in the second divided regions #1 to #(s−1) and #(s+1) to #n out of the plural divided regions #1 to #n.

The differences Δ #1 to Δ #(s−1) and Δ #(s+1) to Δ #n between the first measured wafer pattern D #s and the second measured wafer patterns D #1 to D #(s−1) and D #(s+1) to D #n are calculated.

The target patterns G #1 to G #n are modified based on the differences Δ #1 to Δ #(s−1) and Δ #(s+1) to Δ #n to create the modified target patterns GB #1 to GB #n.

The corrected mask patterns F #1 to F #n are then created based on the modified target patterns GB #1 to GB #n and the model function group M #s.

The modified target patterns GB #1 to GB #n are thus created based on the differences Δ #1 to Δ #(s−1) and Δ #(s+1) to Δ #n between the first measured wafer pattern D #s and the second measured wafer patterns D #1 to D #(s−1) and D #(s+1) to D #n, so that the load of the computation of the optical proximity correction in consideration of the off-axis chromatic aberration in the slit direction can be reduced.
(9) According to the second embodiment, the first divided region #s is closer to the center of the scan field SF in the slit direction, where the test mask patterns E #1 to E #n are transferred in one scan action, than the second divided regions #1 to #(s−1) and #(s+1) to #n.

The test mask patterns E #1 to E #n include the first test mask pattern E #s in the portion of the test mask that corresponds to the first divided region #s, and the second test mask patterns E #1 to E #(s−1) and E #(s+1) to E #n in the portion of the test mask that corresponds to the second divided regions #1 to #(s−1) and #(s+1) to #n.

The processor then creates the model function group M #s based on the first test mask pattern E #s and the first measured wafer pattern D #s.

Since the effect of the off-axis chromatic aberration in the slit direction is small in the first divided region #s close to the center of the scan field SF, the accuracy of the optical proximity correction can be ensured by creating the model function group M #s with respect to the first divided region #s. In the second divided regions #1 to #(s−1) and #(s+1) to #n, the load of the computation of the optical proximity correction in consideration of the off-axis chromatic aberration in slit direction can be reduced by evaluating the off-axis chromatic aberration with respect to the differences Δ #1 to Δ #(s−1) and Δ #(s+1) to Δ #n.
(10) According to the second embodiment, the target mask patterns G #1 to G #n include the first target pattern G #s in the portion of the photosensitive substrate that corresponds to the first divided region #s, and the second target patterns G #1 to G #(s−1) and G #(s+1) to G #n in the portion of the photosensitive substrate that corresponds to the second divided regions #1 to #(s−1) and #(s+1) to #n.

The corrected mask patterns F #1 to F #n include the first corrected mask pattern F #s in the portion of the photomask that corresponds to the first divided region #s, and the second corrected mask patterns F #1 to F #(s−1) and F #(s+1) to F #n in the portion of the photomask that corresponds to the second divided regions #1 to #(s−1) and #(s+1) to #n.

The model function group M #s for predicting the first measured wafer pattern D #s from the first test mask pattern E #s is created based on the first test mask pattern E #s and the first measured wafer pattern D #s.

The first corrected mask pattern F #s is created based on the first target pattern G #s and the model function group M #s.

The second corrected mask patterns F #1 to F #(s−1) and F #(s+1) to F #n are created based on the second target patterns G #1 to G #(s−1) and G #(s+1) to G #n, the model function group M #s, and the measured wafer patterns D #1 to D #n.

The single model function group M #s is thus used to create both the first corrected mask pattern F #s and the second corrected mask patterns F #1 to F #(s−1) and F #(s+1) to F #n, so that the load of the computation of the model functions can be reduced. The description of the creation of the OPC recipe P #s can also be simplified.
(11) According to the second embodiment, the differences Δ #1 to Δ #(s−1) and Δ #(s+1) to Δ #n between the first measured wafer pattern D #s and the second measured wafer patterns D #1 to D #(s−1) and D #(s+1) to D #n are calculated.

The second corrected mask patterns F #1 to F #(s−1) and F #(s+1) to F #n are created based on the differences Δ #1 to Δ #(s−1) and Δ #(s+1) to Δ #n, the second target patterns G #1 to G #(s−1) and G #(s+1) to G #n, and the model function group M #s.

The second corrected mask patterns F #1 to F #(s−1) and F #(s+1) to F #n are thus created based on the differences Δ #1 to Δ #(s−1) and Δ #(s+1) to Δ #n, and the load of the computation of the model functions can be reduced, so that the load of the computation of the corrected mask patterns F #1 to F #n can be reduced.
(12) According to the second embodiment, the modified target patterns GB #1 to GB #(s−1) and GB #(s+1) to GB #n are created by modifying the second target patterns G #1 to G #(s−1) and G #(s+1) to G #n based on the measured wafer patterns D #1 to D #n.

The second corrected mask patterns F #1 to F #(s−1) and F #(s+1) to F #n are created based on the modified target patterns GB #1 to GB #(s−1) and GB #(s+1) to GB #n and the model function group M #s.

The second corrected mask patterns F #1 to F #(s−1) and F #(s+1) to F #n are thus created based on the modified target patterns GB #1 to GB #(s−1) and GB #(s+1) to GB #n, and the load of the computation of the model functions can be reduced, so that the load of the computation of the corrected mask patterns F #1 to F #n can be reduced.
(13) According to the second embodiment, the first test mask pattern E #s and the second test mask patterns E #1 to E #(s−1) and E #(s+1) to E #n each contain a pattern having the same shape.

The load of the computation of the corrected mask patterns F #1 to F #n can therefore be reduced by evaluating the effect of the off-axis chromatic aberration with respect to the differences Δ #1 to Δ #(s−1) and Δ #(s+1) to Δ #n.
(14) According to the second embodiment, the first divided region #s is closer to the center of the scan field SF in the slit direction, where the test mask patterns E #1 to E #n are transferred in one scan action, than the second divided regions #1 to #(s−1) and #(s+1) to #n.

The effect of the off-axis chromatic aberration in the slit direction is small in the first divided region #s close to the center of the scan field SF. The model function group M #s created with respect to the first divided region #s is used to create both the first corrected mask pattern F #s and the second corrected mask patterns F #1 to F #(s−1) and F #(s+1) to F #n, so that the accuracy of the optical proximity correction can be ensured.

As for the other points, the second embodiment is the same as first embodiment.

### 4. Divided-Rule-Based OPC

### 4.1 Operation

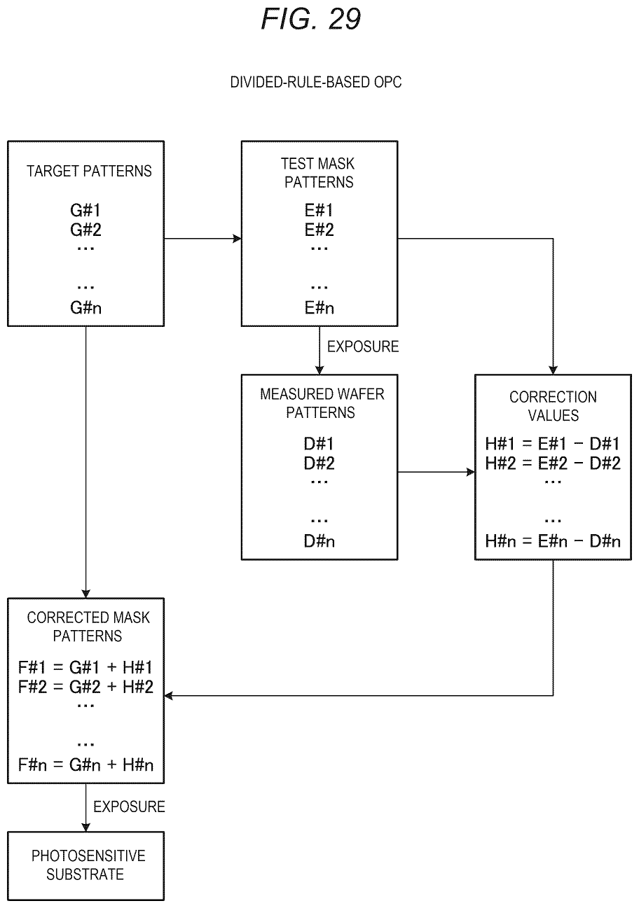

FIG. 29 is a conceptual view of divided-rule-based OPC in a third embodiment. The divided-rule-based OPC differs from the rule-based OPC in Comparative Example in that the target pattern G, the test mask pattern E, the measured wafer pattern D, the correction value H, and the corrected mask pattern F are each created for each of the plural divided regions #1 to #n, and that the rule-based OPC is performed for each of the divided regions #1 to #n. The divided regions #1 to #n have been described with reference to FIG. 19.

The measured wafer pattern D acquired from the scan field SF of the test wafer is segmented into the measured wafer patterns D #1 to D #n in correspondence with the divided regions #1 to #n.

The test mask pattern E is also segmented into the test mask patterns E #1 to E #n in correspondence with the divided regions #1 to #n.

The target pattern G is also segmented into the target patterns G #1 to G #n in correspondence with the divided regions #1 to #n.

The corrected mask pattern F is also segmented into the corrected mask patterns F #1 to F #n in correspondence with the divided regions #1 to #n.

In the divided-rule-based OPC, correction values H #1 to H #n corresponding to the divided regions #1 to #n are calculated.

One of the divided regions #1 to #n in the third embodiment corresponds to the first divided region in the present disclosure, and another corresponds to the second divided region in the present disclosure.

In the third embodiment, for example, when it is assumed that the divided region #1 corresponds to the first divided region in the present disclosure, the measured wafer pattern D #1 corresponds to the first measured wafer pattern in the present disclosure, the test mask pattern E #1 corresponds to the first test mask pattern in the present disclosure, the target pattern G #1 corresponds to the first target pattern in the present disclosure, the corrected mask pattern F #1 corresponds to the first corrected mask pattern in the present disclosure, and the correction value H #1 corresponds to the first correction value in the present disclosure.

When it is assumed that the divided region #2 corresponds to the second divided region in the present disclosure, the measured wafer pattern D #2 corresponds to the second measured wafer pattern in the present disclosure, the test mask pattern E #2 corresponds to the second test mask pattern in the present disclosure, the target pattern G #2 corresponds to the second target pattern in the present disclosure, the corrected mask pattern F #2 corresponds to the second corrected mask pattern in the present disclosure, and the correction value H #2 corresponds to the second correction value in the present disclosure.

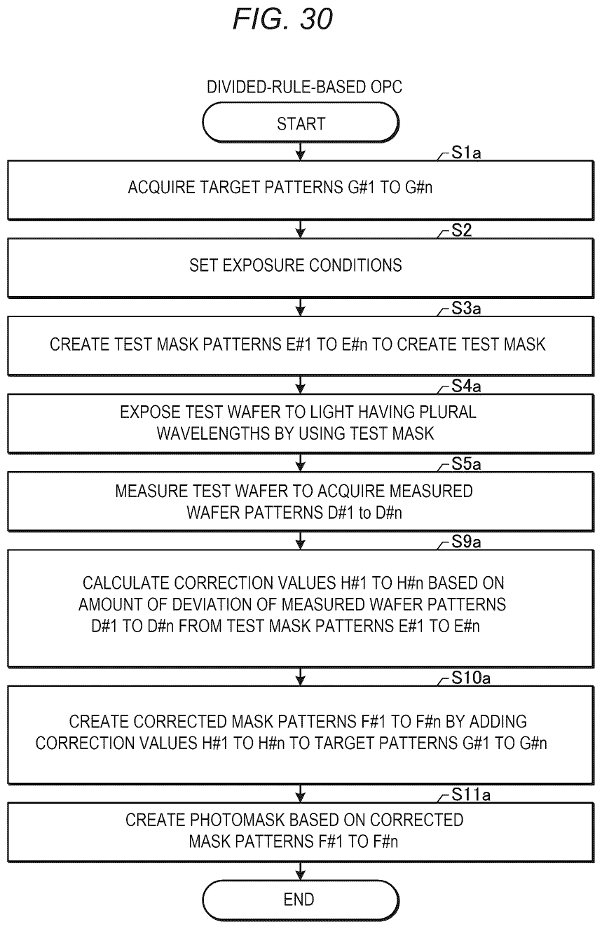

FIG. 30 is a flowchart of the divided-rule-based OPC. The processes shown in FIG. 30 are carried out primarily by a processor, such as the exposure control processor 210.

The processes from S1a to S5a and S11a are the same as the processes in the divided-model-based OPC described with reference to FIG. 20.

In S9a, the processor calculates the correction values H #1 to H #n based on the amounts of deviation of the measured wafer patterns D #1 to D #n from the test mask patterns E #1 to E #n, respectively. For example, the correction value H #1 is calculated based on the amount of deviation of the measured wafer pattern D #1 from the test mask pattern E #1, and the correction value H #2 is calculated based on the amount of deviation of the measured wafer pattern D #2 from the test mask pattern E #2.

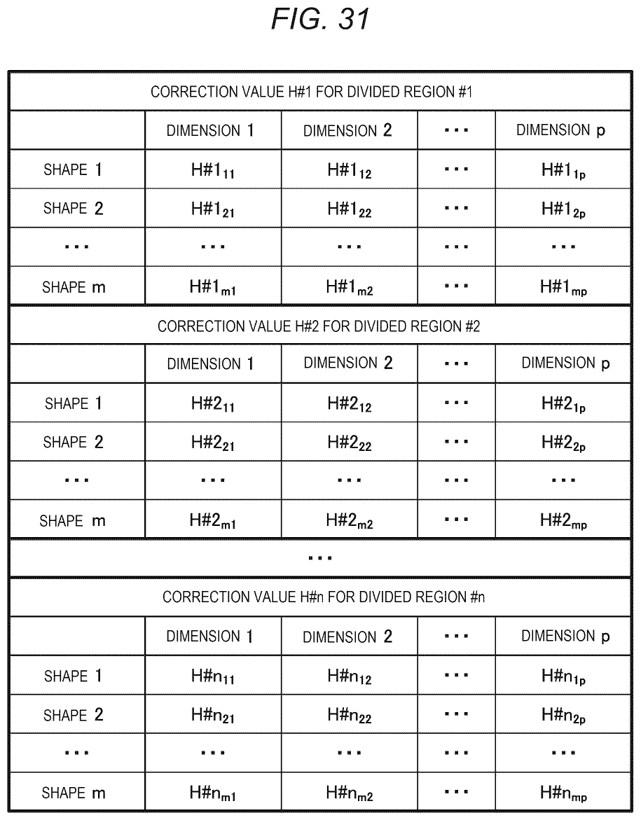

FIG. 31 shows the structure of data on the correction values H #1 to H #n. The correction values H #1 to H #n each contain correction values corresponding to the p measured dimensions of each of the m shapes 1 to m. For example, the correction value H #1 includes correction values H #1₁₁ to H #1ₘₚ, the correction value H #2 includes correction values H #2₁₁ to H #2ₘₚ, and the correction value H #n includes correction values H #n₁₁ to H #nₘₚ.

Referring again to FIG. 30, the processor creates in S10a the corrected mask patterns F #1 to F #n by adding the correction values H #1 to H #n to the target patterns G #1 to G #n, respectively. The processor creates, for example, the corrected mask pattern F #1 based on the target pattern G #1 and the correction value H #1, and the corrected mask pattern F #2 based on the target pattern G #2 and the correction value H #2.

### 4.2 Effects

(15) According to the third embodiment, the correction values H #1 to H #n are calculated based on the amounts of deviation of the measured wafer patterns D #1 to D #n from the test mask patterns E #1 to E #n, respectively.

The corrected mask patterns F #1 to F #n are then created based on the target patterns G #1 to G #n and the correction values H #1 to H #n.

The corrected mask patterns F #1 to F #n can thus be created by using the correction values H #1 to H #n based on the results of the measurement in the divided regions #1 to #n to perform the optical proximity correction through simple computation in consideration of the off-axis chromatic aberration in the slit direction.
(16) According to the third embodiment, the plural correction values H #1 to H #n are calculated for the respective divided regions #1 to #n.

The corrected mask patterns F #1 to F #n can therefore be created by calculating the correction values H #1 to H #n for the respective divided regions #1 to #n and performing the optical proximity correction in consideration of the off-axis chromatic aberration in the slit direction on a divided region basis.
(17) According to the third embodiment, the measured wafer patterns D #1 to D #n include the first measured wafer pattern D #1 in the first divided region #1 out of the plural divided regions #1 to #n, and the second measured wafer pattern D #2 in the second divided region #2 out of the plural divided regions #1 to #n.

The test mask patterns E #1 to E #n include the first test mask pattern E #1 in the portion of the test mask that corresponds to the first divided region #1, and the second test mask pattern E #2 in the portion of the test mask that corresponds to the second divided region #2.

The target patterns G #1 to G #n include the first target pattern G #1 in the portion of the photosensitive substrate that corresponds to the first divided region #1, and the second target pattern G #2 in the portion of the photosensitive substrate that corresponds to the second divided region #2.

The corrected mask patterns F #1 to F #n include the first corrected mask pattern F #1 in the portion of the photomask that corresponds to the first divided region #1, and the second corrected mask pattern F #2 in the portion of the photomask that corresponds to the second divided region #2.

The first correction value H #1 is calculated based on the amount of deviation of the first measured wafer pattern D #1 from the first test mask pattern E #1, and the second correction value H #2 is calculated based on the amount of deviation of the second measured wafer pattern D #2 from the second test mask pattern E #2.

Thereafter, the first corrected mask pattern F #1 is created based on the first target pattern G #1 and the first correction value H #1, and the second corrected mask pattern F #2 is created based on the second target pattern G #2 and the second correction value H #2.

The optical proximity correction in consideration of the off-axis chromatic aberration in the slit direction can therefore be performed by calculating the first correction value H #1 using the first test mask pattern E #1 and the first measured wafer pattern D #1 corresponding to the first divided region #1, and by calculating the second correction value H #2 using the second test mask pattern E #2 and the second measured wafer pattern D #2 corresponding to the second divided region #2.
(18) According to the third embodiment, the first test mask pattern E #1 and the second test mask pattern E #2 each contain a pattern having the same shape.

Therefore, the test mask is readily manufactured, and the test wafer is readily measured, so that the data are readily handled.

As for the other points, the third embodiment is the same as the rule-based OPC in Comparative Example.

### 5. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of any thereof and any other than A, B, and C.

What is claimed is:

1. A method for creating a photomask used in photolithography using pulse laser light having plural center wavelengths, the method comprising:
scanning a test wafer in a first direction with the pulse laser light via a test mask to pattern the test wafer;
measuring a wafer pattern of the patterned test wafer to acquire a measured wafer pattern indicating a result of the measurement in each of plural divided regions arranged on a surface of the test wafer in a second direction that intersects with the first direction;
creating a corrected mask pattern for creating the photomask based on a test mask pattern formed at the test mask, the measured wafer pattern, and a target pattern that is a target wafer pattern at a photosensitive substrate; and
creating the photomask based on the corrected mask pattern.

2. The creation method according to claim 1, wherein
a model function for predicting the measured wafer pattern from the test mask pattern is created based on the test mask pattern and the measured wafer pattern, and
the corrected mask pattern is created based on the target pattern and the model function.

3. The creation method according to claim 2, wherein
the model function is created by performing an exposure simulation using light having center wavelengths the number of which is smaller than the number of the center wavelengths of the pulse laser light by using the test mask pattern.

4. The creation method according to claim 2, wherein
the model function includes plural model functions created for the plural respective divided regions, and
the corrected mask pattern is created based on the target pattern and the plural model functions.

5. The creation method according to claim 2, wherein
the measured wafer pattern includes a first measured wafer pattern in a first divided region out of the plural divided regions, and a second measured wafer pattern in a second divided region out of the plural divided regions,
the test mask pattern includes a first test mask pattern in a portion of the test mask that corresponds to the first divided region, and a second test mask pattern in a portion of the test mask that corresponds to the second divided region,
the model function includes a first model function created for the first divided region, and a second model function created for the second divided region,
the first model function is created based on the first test mask pattern and the first measured wafer pattern,
the second model function is created based on the second test mask pattern and the second measured wafer pattern, and
the corrected mask pattern is created based on the target pattern and the first and second model functions.

6. The creation method according to claim 5, wherein
the first and second test mask patterns each contain a pattern having the same shape.

7. The creation method according to claim 2, wherein
the plural divided regions include first and second divided regions,
the target pattern includes a first target pattern in a portion of the photosensitive substrate that corresponds to the first divided region, and a second target pattern in a portion of the photosensitive substrate that corresponds to the second divided region,
the model function includes a first model function created for the first divided region, and a second model function created for the second divided region,
the corrected mask pattern includes a first corrected mask pattern in a portion of the photomask that corresponds to the first divided region, and a second corrected mask pattern in a portion of the photomask that corresponds to the second divided region,
the first corrected mask pattern is created based on the first target pattern and the first model function, and
the second corrected mask pattern is created based on the second target pattern and the second model function.

8. The creation method according to claim 2, wherein
the measured wafer pattern includes a first measured wafer pattern in a first divided region out of the plural divided regions, and a second measured wafer pattern in a second divided region out of the plural divided regions,
a difference between the first measured wafer pattern and the second measured wafer pattern is calculated,
a modified target pattern is created by modifying the target pattern based on the difference, and
the corrected mask pattern is created based on the modified target pattern and the model function.

9. The creation method according to claim 8, wherein
the first divided region is closer than the second divided region to a center, in the second direction, of a region to which the test mask pattern is transferred in one scan action,
the test mask pattern includes a first test mask pattern in a portion of the test mask that corresponds to the first divided region, and a second test mask pattern in a portion of the test mask that corresponds to the second divided region, and
the model function is created based on the first test mask pattern and the first measured wafer pattern.

10. The creation method according to claim 1, wherein
the measured wafer pattern includes a first measured wafer pattern in a first divided region out of the plural divided regions, and a second measured wafer pattern in a second divided region out of the plural divided regions,
the test mask pattern includes a first test mask pattern in a portion of the test mask that corresponds to the first divided region, and a second test mask pattern in a portion of the test mask that corresponds to the second divided region,
the target pattern includes a first target pattern in a portion of the photosensitive substrate that corresponds to the first divided region, and a second target pattern in a portion of the photosensitive substrate that corresponds to the second divided region,
the corrected mask pattern includes a first corrected mask pattern in a portion of the photomask that corresponds to the first divided region, and a second corrected mask pattern in a portion of the photomask that corresponds to the second divided region,
a model function for predicting the first measured wafer pattern from the first test mask pattern is created based on the first test mask pattern and the first measured wafer pattern,
the first corrected mask pattern is created based on the first target pattern and the model function, and
the second corrected mask pattern is created based on the second target pattern, the model function, and the first and second measured wafer patterns.

11. The creation method according to claim 10, wherein
a difference between the first measured wafer pattern and the second measured wafer pattern is calculated, and
the second corrected mask pattern is created based on the difference, the second target pattern, and the model function.

12. The creation method according to claim 10, wherein
a modified target pattern is created by modifying the second target pattern based on the first and second measured wafer patterns, and
the second corrected mask pattern is created based on the modified target pattern and the model function.

13. The creation method according to claim 10, wherein
the first and second test mask patterns each contain a pattern having the same shape.

14. The creation method according to claim 10, wherein
the first divided region is closer than the second divided region to a center, in the second direction, of a region to which the test mask pattern is transferred in one scan action.

15. The creation method according to claim 1, wherein
a correction value is calculated based on an amount of deviation of the measured wafer pattern from the test mask pattern, and
the corrected mask pattern is created based on the target pattern and the correction value.

16. The creation method according to claim 15, wherein
the correction value contains plural correction values calculated for the respective divided regions, and
the corrected mask pattern is created based on the target pattern and the plural correction values.

17. The creation method according to claim 1, wherein
the measured wafer pattern includes a first measured wafer pattern in a first divided region out of the plural divided regions, and a second measured wafer pattern in a second divided region out of the plural divided regions,
the test mask pattern includes a first test mask pattern in a portion of the test mask that corresponds to the first divided region, and a second test mask pattern in a portion of the test mask that corresponds to the second divided region,
the target pattern includes a first target pattern in a portion of the photosensitive substrate that corresponds to the first divided region, and a second target pattern in a portion of the photosensitive substrate that corresponds to the second divided region,
the corrected mask pattern includes a first corrected mask pattern in a portion of the photomask that corresponds to the first divided region, and a second corrected mask pattern in a portion of the photomask that corresponds to the second divided region,
a first correction value is calculated based on an amount of deviation of the first measured wafer pattern from the first test mask pattern,
a second correction value is calculated based on an amount of deviation of the second measured wafer pattern from the second test mask pattern,
the first corrected mask pattern is created based on the first target pattern and the first correction value, and
the second corrected mask pattern is created based on the second target pattern and the second correction value.

18. The creation method according to claim 17, wherein
the first and second test mask patterns each contain a pattern having the same shape.

19. A method for creating data on a corrected mask pattern for creating a photomask used in photolithography using pulse laser light having plural center wavelengths, the method comprising:
scanning a test wafer in a first direction with the pulse laser light via a test mask to pattern the test wafer;
measuring a wafer pattern of the patterned test wafer to acquire a measured wafer pattern indicating a result of the measurement in each of plural divided regions arranged on a surface of the test wafer in a second direction that intersects with the first direction; and
creating the corrected mask pattern based on a test mask pattern formed at the test mask, the measured wafer pattern, and a target pattern that is a target wafer pattern at a photosensitive substrate.

20. An electronic device manufacturing method comprising:
scanning a test wafer in a first direction with pulse laser light having plural center wavelengths via a test mask to pattern the test wafer;
measuring a wafer pattern of the patterned test wafer to acquire a measured wafer pattern indicating a result of the measurement in each of plural divided regions arranged on a surface of the test wafer in a second direction that intersects with the first direction;
creating a corrected mask pattern for creating a photomask used in photolithography using the pulse laser light based on a test mask pattern formed at the test mask, the measured wafer pattern, and a target pattern that is a target wafer pattern at a photosensitive substrate;
creating the photomask based on the corrected mask pattern; and
exposing the photosensitive substrate to the pulse laser light via the photomask to manufacture electronic devices.
